(19) United States
(12) Patent Application Publication
(10) Pub. No.: US 2025/0161923 A1
(43) Pub. Date: May 22, 2025

(54) SINGLE CRYSTALLINE TA3N5 NANOPARTICLES MODIFIED WITH A MOX COCATALYST, A CATALYST, METHODS FOR WATER SPLITTING USING THE CATALYST, AND METHODS TO MAKE SAME

(71) Applicants: Global Advanced Metals USA, Inc., Wellesley Hills, MA (US); Shinshu University, Nagano (JP)

(72) Inventors: Kazunari DOMEN, Nagano (JP); Takashi HISATOMI, Nagano (JP); Mary KRAUSE, Phoenixville, PA (US); Aijun YIN, Schwenksville, PA (US); Gordon SMITH, Arlington Heights, IL (US)

(73) Assignees: Global Advanced Metals USA, Inc., Wellesley Hills, MA (US); Shinshu University, Nagano (JP)

(21) Appl. No.: 18/836,366

(22) PCT Filed: Feb. 14, 2023
(86) PCT No.: PCT/US2023/012963

§ 371 Date: Aug. 7, 2024

Related U.S. Application Data
(60) Provisional application No. 63/310,237, filed on Feb. 15, 2022.

(51) Int. Cl. B01J 27/24; B01J 23/847; B01J 35/39; B01J 35/40; B01J 35/45; B01J 37/02; B01J 37/08; C01B 3/04; C30B 29/38

(52) U.S. Cl. CPC B01J 27/24; B01J 23/8476; B01J 35/39; B01J 35/40; B01J 35/45; B01J 37/0225; B01J 37/0236; B01J 37/0242; B01J 37/08; C01B 3/042; C30B 29/38

(57) ABSTRACT

Tantalum nitride and specifically a novel Ta₃N₅ nanoparticles, such as single crystalline Ta₃N₅ nanoparticles, are disclosed. The nanoparticles used with a co-catalyst is further disclosed. The present invention also relates to Ta₃N₅ nanoparticles modified with a metal oxide, such as a CoOₓcocatalyst, wherein Oₓ represents an oxide that is part of the cobalt oxide. A catalyst, such as for water oxidation to produce O₂, is disclosed. The nanoparticles can further be modified to include a water reducing catalyst. A water splitting catalyst is further disclosed. Methods of making the nanoparticles and catalyst are also disclosed. Methods to split water utilizing the catalyst are further described.

This application claims the benefit under 35 U.S.C. § 119(e) of prior U.S. Provisional Patent Application No. 63/310,237 filed Feb. 15, 2022, which is incorporated in its entirety by reference herein.

### BACKGROUND OF THE INVENTION

Water splitting to form hydrogen and oxygen using solar energy in the presence of photocatalysts has been studied as a potential means of clean, large-scale fuel production. Hydrogen fuel production has gained increased attention with the concerns about global warming. Methods such as photocatalytic water splitting are being investigated to produce hydrogen, a clean-burning fuel. Water splitting holds particular promise since it utilizes water, an inexpensive renewable resource. Photocatalytic water splitting has the simplicity of using a catalyst and sunlight to produce hydrogen out of water.

In contrast to the two-step system of photovoltaic production of electricity and subsequent electrolysis of water, photocatalytic water splitting processes are performed by photocatalysts being in direct contact with water. The photocatalysts are either in homogeneous environments with respect to the water (photocatalysts suspended within the water) or are in a heterogeneous phase with respect to the water (photocatalysts bound to a surface in contact with the water). Examples of heterogeneous photocatalytic processes include that described in U.S. Pat. No. 10,744,495 and US2014/0174905, and these patent methods can be utilized with the present invention's catalyst and are incorporated in their entirety by reference herein. Whether homogeneous or heterogeneous, photocatalytic water splitting is more efficient than the two-step process of water electrolysis.

The prime measure of photocatalyst effectiveness is quantum yield (QY), which is: QY (%)=(Photochemical reaction rate)/(Photon absorption rate)×100%. This quantity is a reliable determination of how effective a photocatalyst is. Overall, the best photocatalyst has a high quantum yield and gives a high rate of gas evolution. Almost all the reported photocatalytic water-splitting systems suffer from low QY in the visible-light region (e.g., rarely exceeding 3% at 420 nm), which largely hinders any potential practical applications.

In order to solve the worldwide rising problems concerning the energy shortage and environmental decay, artificial photosynthesis (photocatalytic water splitting and CO₂ reduction) is a promising way to convert solar energy into high value-added chemical energy (Chen, X. B.; Li, C.; Grätzel, M.; Kostecki, R.; Mao, S. S. Nanomaterials for renewable energy production and storage. Chem. Soc. Rev. 2012, 41, 7909-7937; and Wang, Z.; Li, C.; Domen, K. Recent developments in heterogeneous photocatalysts for solar-driven overall water splitting. Chem. Soc. Rev. 2019, 48, 2109-2125).

Photocatalytic water splitting generally involves two separate reaction pathways leading to the production of hydrogen and oxygen: 2H₂O⇒2H₂+O₂.

A photocatalyst can enhance the hydrogen pathway catalyzing the corresponding reduction reaction, and/or the photocatalyst can enhance the oxygen pathway catalyzing the corresponding oxidation reaction. It would be desirable to utilize a photocatalyst(s) that can simultaneously promote the hydrogen pathway and also promote the oxygen pathway, and do so in an efficient manner.

Water oxidation (with four-electron transfer and O═O bond formation) is an important step not only for water splitting into H₂ and O₂, but also for CO₂ reduction into carbon-containing chemicals (Wang, Y.; Suzuki, H.; Xie, J.; Tomita, O.; Martin, D. J.; Higashi, M.; Kong, D.; Abe, R.; Tang, J. W. Mimicking natural photosynthesis: solar to renewable H₂ Fuel synthesis by Z-scheme water splitting systems. Chem. Rev. 2018, 118, 5201-5241; and Wang, Z.; Teramura, K.; Hosokawa, S.; Tanaka, T. Highly efficient Photocatalytic conversion of CO₂ into solid CO using H₂O as a reductant over Ag-modified ZnGa₂O₄. J. Mater. Chem. A 2015, 3, 11313-11319; and Kudo, A; Miseki, Y. Heterogeneous photocatalyst materials for water splitting. Chem. Soc. Rev. 2009, 38, 253-278.)

Since the visible light (wavelength between 400 nm and 800 nm) occupies a large portion in the solar spectrum, it can be important to develop semiconductor photocatalysts that can respond under the wide visible light irradiation for the expected solar energy conversion efficiency. Ta₃N₅ has been considered for solar water splitting, because of its simple chemical composition and narrow band gap energy (2.1 eV) with suitable band position straddling the water redox potentials. It has been reported Ta₃N₅ enables H₂ or O₂ evolution from half reactions (Yuliati, L.; Yang, J. H.; Wang, X. C.; Maeda, K.; Takata, T.; Antonietti, M.; Domen; and Highly active tantalum(V) nitride nanoparticles prepared from a mesoporous carbon nitride template for photocatalytic hydrogen evolution under visible light irradiation. J. Mater. Chem. 2010, 20, 4295-4298; and Qi, Y.; Chen, S. S.; Li, M. R.; Ding, Q.; Li, Z.; Cui, J. Y.; Dong, B. B.; Zhang, F. X.; Li, C. Achievement of visible-light-driven Z-scheme overall water splitting using barium-modified Ta₃N₅ as a H₂-evolving photocatalyst. Chem. Sci. 2017, 8, 437-443; and Hou, J. G.; Wu, Y. Z.; Cao, S. Y.; Liang, F.; Lin, Z. S.; Gao, Z. M.; Sun, L. C. In situ phase-induced spatial charge separation in core-shell oxynitride nanocube heterojunctions realizing robust solar water splitting. Adv. Energy Mater. 2017, 7, 1700171; and Nurlaela, E.; Ould-Chikh, S.; Llorens, I.; Hazemann, J.; Takanabe, K. Establishing efficient cobalt-based catalytic sites for oxygen evolution on a Ta₃N₅ photocatalyst. Chem. Mater. 2015, 27, 5685-5694) and one-step excitation overall water splitting (Wang, Z.; Inoue, Y.; Hisatomi, T.; Ishikawa, R.; Wang, Q.; Takata, T.; Chen, S. S.; Shibata, N.; Ikuhara, Y.; Domen, K. Overall water splitting by Ta₃N₅ nanorod single crystals grown on the edges of KTaO₃ particles. Nat. Catal. 2018, 1, 756-763.)

Owing to its water oxidation capacity, considerable improvements in Z-scheme water splitting and photoelectrochemical water splitting using Ta₃N₅ for O₂ evolution have been achieved (Tabata, M.; Maeda, K.; Higashi, M.; Lu, D.; Takata, T.; Abe, R.; Domen, K. Modified Ta₃N₅ powder as a photocatalyst for O₂ evolution in a two-step water splitting system with an iodate/iodide shuttle redox mediator under visible light. Langmuir 2010, 26, 9161-9165; and Ma, S. S.; Maeda, K.; Hisatomi, T.; Tabata, M.; Kudo, A.; Domen, K. A redox-mediator-free solar-driven Z-scheme water-splitting system consisting of modified Ta₃N₅ as an oxygen-evolution photocatalyst. Chem. Eur. J. 2013, 19, 7480-7486; and Liu, G. J.; Ye, S.; Yan, P. L.; Xiong, F. Q.; Fu, P.; Wang, Z. L.; Chen, Z.; Shi, J. Y.; Li, C. Enabling an integrated tantalum nitride photoanode to approach the theoretical photocurrent limit for solar water splitting. Energy Environ. Sci. 2016, 9, 1327-1334 (2016); and Zhong, M.; Hisatomi, T.; Sasaki, Y.; Suzuki, S.; Teshima, K.; Nakabayashi, M.; Shibata, N.; Nishiyama, H.; Katayama, M.; Yamada, T.; Domen, K. Highly active GaN-stabilized Ta₃N₅ thin-film photoanode for solar water oxidation. Angew. Chem. Int. Ed. 2017, 56, 4739-4743).

Good-quality Ta₃N₅ photocatalyst is highly desirable to efficiently enhance the separation of photoexcited charges and the migration of electrons and holes to surface sites for photocatalytic reactions. Conventional Ta₃N₅ photocatalyst is generally prepared by nitridation of powdered Ta₂O₅ precursor under an NH₃ flow at high temperatures and prolonged term, consisting of aggregated polycrystalline particulates with crystal defects and impurity energy levels, which are detrimental to the photocatalytic water oxidation activity. Modification with alkaline metal or magnesium oxide to tailor the morphology and surface property of Ta₃N₅ from Ta₂O₅ precursor are necessary to boost efficient photocatalytic O₂ evolution. When KTaO₃ having lattice spacing close to that for Ta₃N₅ and a potassium component that readily vaporizes at high temperatures was applied as a unique starting metal oxide, Ta₃N₅ nanorod single crystals with minimized defect states were fast grown on KTaO₃ cubes in a short NH₃ nitridation process and exhibited simultaneous H₂ and O₂ evolutions in visible-light-driven one-step excitation overall water splitting. This demonstrates that the precursor for the synthesis of Ta₃N₅ has an essential function in operating the morphology, crystallinity, nanostructure and defect states of Ta₃N₅ towards efficient solar to chemical energy conversion. Metallic Ta particles can be regarded as a promising material for the growth of well-crystallized Ta₃N₅ photocatalyst, because the oxidation reaction of Ta metal with NH₃ at high-temperature nitridation is different from O-to-N substitution for Ta₂O₅ precursor, which largely shortens the nitridation process. It is reported that Ta metal powder produced single-phase Ta₃N₅ whereas Ta₂O₅ did not at the same short-term nitridation process. Moreover, the doped nanoparticulate Ta₃N₅ single crystals synthesized from Ta metal nanopowder by a brief NH₃ nitridation process exhibited a dramatically enhanced photocatalytic water reduction activity (H₂ production), indicating the advanced availability of the nanosized Ta metal precursor (Ma, S.; Hisatomi, T.; Maeda, K.; Moriya, Y.; Domen, K. Enhanced water oxidation on Ta₃N₅ photocatalysts by modification with alkaline metal salts. J. Am. Chem. Soc. 2012, 134, 19993-19996; and Chen, S. S.; Shen, S.; Liu, G. J.; Qi, Y.; Zhang, F. X.; Li, C. Interface engineering of a CoOx/Ta₃N₅ photocatalyst for unprecedented water oxidation performance under visible-light-irradiation. Angew. Chem. Int. Ed. 2015, 54, 3047-3051; and Suzuki, S.; Ando, R.; Matsui, Y.; Isechi, K.; Yubuta, K.; Teshima, K. Prismatic Ta₃N₅-composed spheres produced by self-sacrificial template-like conversion of Ta particles via Na₂CO₃ flux. CrystEngComm 2020, 22, 5122-5129; and Xiao, J. D.; Vequizo, J. J.; Hisatomi, T.; Rabeah, J.; Nakabayashi, M.; Wang, Z.; Xiao, Q.; Li, H. H.; Pan, Z. H.; Krause, M.; Yin, N.; Smith, G.; Shibata, N.; Brückner, A.; Yamakata, A.; Takata, T.; Domen, K. Simultaneously Tuning the defects and surface properties of Ta₃N₅ nanoparticles by Mg—Zr codoping for significantly accelerated photocatalytic H₂ evolution. J. Am. Chem. Soc. 2021, 143, 10059-10064).

Ta₃N₅ is regarded as a promising photocatalyst for solar water splitting, because of its superior visible-light absorption and simple crystal component. However, conventional Ta₃N₅ photocatalyst from an oxide precursor generally has aggregated polycrystalline particulates with defect states and a grain boundary, which confines the significant enhancement of photocatalytic water oxidation activity.

Thus, there is a need to provide an improved Ta₃N₅ nanoparticle and catalyst that can be a single crystalline nanoparticle and/or provides improved catalytic properties such as, but not limited to, improved photocatalytic water oxidation activity.

Accordingly, there is a need in the industry to provide improved nanoparticles and especially improved tantalum nitrides that find use, for instance, as catalyst and for use in methods for water splitting and/or other uses.

### SUMMARY OF THE PRESENT INVENTION

It is therefore a feature of the present invention to provide a novel tantalum nitride and specifically a novel Ta₃N₅ nanoparticles, such as single crystalline Ta₃N₅ nanoparticles.

A further feature is to provide Ta₃N₅ nanoparticles that can be used with at least one co-catalyst.

Another feature of the present invention is to provide a catalyst, such as for water oxidation to produce O₂.

Another feature of the present invention is to provide a single catalyst, such as for water oxidation to produce O₂ and also for water reduction to produce H₂.

Another feature of the present invention is to provide catalysts, such as for water oxidation to produce O₂ and also for water reduction to produce H₂ by way of a catalyst mixture of a water oxidation catalyst and a water reduction catalyst.

Another feature of the present invention is to provide a water splitting catalyst.

Another feature of the present invention is to provide a method to water split using nanoparticles such as in the form of a catalyst.

Another feature of the present invention is to provide methods of making the novel tantalum nitrides and catalysts.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention in part, relates to tantalum nitrides, in particular Ta₃N₅, and products containing or made from the Ta₃N₅, such as, but not limited to, a catalyst.

The present invention also relates to Ta₃N₅ nanoparticles modified with a metal oxide, such as a CoOₓ cocatalyst, wherein Oₓ represents an oxide that is part of the cobalt oxide.

The present invention further relates to single crystalline Ta₃N₅ nanoparticles modified with a metal oxide, such as a CoOₓ cocatalyst, wherein Oₓ represents an oxide that is part of the cobalt oxide.

In addition, the present invention relates to a photocatalyst that contains or is Ta₃N₅ nanoparticles (e.g., single crystalline) modified with a metal catalyst, such as a CoOₓ cocatalyst, wherein Oₓ represents an oxide that is part of the cobalt oxide.

Also, the present invention relates to a catalyst that includes the single crystalline Ta₃N₅ nanoparticles modified with a metal oxide cocatalyst, such as a CoOₓ cocatalyst, with platinum and/or other catalyst metal distributed on a surface of the single crystalline nanoparticles.

Further, the present invention relates to a catalyst that contains or is Ta₃N₅ nanoparticles (e.g., single crystalline) 1) modified with a metal catalyst, such as a CoOₓ cocatalyst, wherein Oₓ represents an oxide that is part of the cobalt oxide and 2) modified or doped with one or two metals such as Zr and/or Mg (e.g., Ta₃N₅:Mg+Zr, or Ta₃N₅:Mg, or Ta₃N₅:Zr or any combination thereof).

The co-catalyst(s) can be impregnated, attached, distributed, or dispersed on or used with the single crystalline nanoparticles.

Further, the present invention relates to a mixture of catalysts, where a first catalyst is a water oxidation catalyst and the second catalyst is a water reducing catalyst (or water reduction catalyst). For example, the mixture can be wherein a first catalyst contains or is Ta₃N₅ nanoparticles (e.g., single crystalline) modified with a metal catalyst, such as a CoOₓ cocatalyst, wherein Oₓrepresents an oxide that is part of the cobalt oxide and a second catalyst is modified or doped with one or two metals such as Zr and/or Mg (e.g., Ta₃N₅:Mg+Zr, or Ta₃N₅:Mg, or Ta₃N₅:Zr or any combination thereof).

The present invention further relates to a catalyst that includes the single crystalline nanoparticles of the present invention along with the metal oxide catalyst (e.g., CoOₓ co-catalyst(s)), and further including a co-catalyst that can be a platinum metal (Pt) that is homogeneously distributed or dispersed on the single crystalline nanoparticles or mixed with the nanoparticles or used in combination with the nanoparticles.

The present invention further relates to a catalyst that includes the single crystalline nanoparticles of the present invention along with the metal co-catalyst (e.g., the CoOₓ co-catalyst(s)) for use as a water oxidation catalyst, in combination with a water reducing catalyst. For instance, the water reducing catalyst for the reduction reaction can, as an option, utilize single crystalline nanoparticles that are tantalum nitride doped with at least one metal. The reduction reaction can utilize single crystalline nanoparticles that are Ta₃N₅:Mg+Zr, or Ta₃N₅:Mg, or Ta₃N₅:Zr or any combination thereof. The reduction reaction can utilize single crystalline nanoparticles that are Ta₃N₅:Mg+Zr, or Ta₃N₅:Mg, or Ta₃N₅:Zr or any combination thereof along with at least one co-catalyst (e.g., Pt).

Further, the present invention relates to a method to water split, and method includes the step of utilizing the catalyst (e.g., photocatalyst) of the present invention in contact with water or other fluid. The method can further include the use of a further catalyst (e.g., photocatalyst), where one catalyst is a water oxidation catalyst as described herein and the further catalyst is a water reducing catalyst as described in U.S. Provisional Patent Application No. 63/184,816 filed May 6, 2021 or WO 2022/235721, incorporated in their entirety by reference herein. The two catalysts can be used a mixture on the same single crystalline nanoparticles of the present invention, or can be used together as a mixture of nanoparticles and introduced or used in any sequence.

Further, the present invention relates to a method to water split, and method includes the step of utilizing a catalyst (e.g., photocatalyst) of the present invention in contact with water or other fluid. The single/same catalyst has dual functions, namely, a water oxidation catalyst as described herein and the further a water reducing catalyst as described in U.S. Provisional Patent Application No. 63/184,816 filed May 6, 2021 or WO 2022/235721, incorporated in their entirety by reference herein.

The present invention also relates to a method to make the nanoparticles or catalyst of the present invention, which includes subjecting either a spherical tantalum powder or tantalum aggregates with a salt aggregate or a flame synthesized tantalum that can optionally be encapsulated with a salt to a nitridation process, with the nitridation process including conducting nitridation under a flow of NH₃, at a temperature of 700 K or higher for 10 minutes to 4 hours or more to form a tantalum nitride and then impregnating the tantalum nitride with a metal oxide cocatalyst such as CoOₓ as the cocatalyst.

It is to be understood that both the foregoing general description and the following detailed description are exemplary and explanatory only and are intended to provide a further explanation of the present invention, as claimed.

### BRIEF DESCRIPTION OF THE DRAWINGS

FIG. 1 is XRD patterns for (a) the Ta nanoparticulate precursor (w/oNaCl/Ta), and the products generated by nitridation at (b) 773 K, (c) 923 K, (d) 1023 K, (e) 1073 K, (f) 1123 K and (g) 1173 K for 10 min, and of (h) the Ta₃N₅ obtained from the Ta nanopowder (w/oNaCl/Ta) nitrided at 1173 K for 4 h, used in an example of the present application.

FIG. 2A are XRD patterns obtained from Ta₃N₅ nanoparticles produced using Ta nanopowder (w/oNaCl/Ta) nitrided at different temperatures for 4 h.

FIG. 2B is UV-Vis DRS data obtained from Ta₃N₅ nanoparticles produced using Ta nanopowder (w/oNaCl/Ta) nitrided at different temperatures for 4 h.

FIG. 2C is a bar graph showing nitridation temperature vs. rate of O₂ evolution for catalysts of the present invention. Photocatalytic O₂ evolution over these Ta₃N₅ nanoparticles. Conditions: catalyst, 0.15 g; CoOₓ loading, 0.5 wt %; 0.2 M aqueous AgNO₃ solution, 150 mL; La₂O₃ buffer, 0.15 g; light source, 300 W xenon lamp (λ≥420 nm).

FIG. 2D is an SEM image of the Ta₃N₅ nanoparticles made by nitridation of Ta nanopowder (w/oNaCl/Ta) at 1173 K for 4 h.

FIG. 2E are HRTEM and SAED images of Ta₃N₅ nanoparticles made by nitridation of Ta nanopowder (w/oNaCl/Ta) at 1173 K for 4 h.

FIG. 3A are XRD patterns and FIG. 3B is a bar graph showing photocatalytic O₂ evolution activities for Ta₃N₅ nanoparticles made from NaCl-mixed Ta nanopowder (NaCl/Ta) nitrided at different temperatures for 16 h. Conditions: catalyst, 0.15 g; CoOₓ loading, 0.5 wt %; 0.2 M aqueous AgNO₃ solution, 150 mL; La₂O₃ buffer, 0.15 g; light source, 300 W xenon lamp (λ≥420 nm).

FIG. 3C are SEM images of these nanoparticles of FIG. 3A.

FIG. 3D are HRTEM images of Ta₃N₅ nanoparticles made from NaCl-mixed Ta nanopowder (NaCl/Ta) nitrided at 1073 K for 16 h. FIG. 4 is a graph of Wavelength vs. AQY: Apparent quantum yield of Ta₃N₅ nanoparticles

made from NaCl-mixed Ta nanopowder (NaCl/Ta) nitrided at 1073 K for 16 h during photocatalytic O₂ evolution as a function of the incident light wavelength. Conditions: catalyst, 0.15 g; CoOₓ loading, 0.5 wt %; 0.2 M aqueous AgNO₃ solution, 150 mL; La₂O₃ buffer, 0.15 g; light source, 300 W xenon lamp equipped with various band-pass filters.

FIG. 5 is an SEM image of Ta metal nanopowder (w/oNaCl/Ta) that was nitrided in an example of the present invention to form Ta₃N₅.

FIG. 6 is a graph of Irradiation Time vs. Amount of O₂ evolved: Time course of photocatalytic O₂ evolution over Ta₃N₅ nanoparticles produced using Ta nanopowder (w/oNaCl/Ta) nitrided at different temperatures for 4 h. Conditions: catalyst, 0.15 g; CoOₓ loading, 0.5 wt %; 0.2 M aqueous AgNO₃ solution, 150 mL; La₂O₃ buffer, 0.15 g; light source, 300 W xenon lamp (λ≥420 nm).

FIG. 7A are XRD patterns and FIG. 7B is a graph of nitridation time vs. Rate of O₂ evolution, specifically photocatalytic O₂ evolution activities for Ta₃N₅ nanoparticles obtained from the nitridation of Ta nanopowder (w/oNaCl/Ta) at 1173 K for different time spans. Conditions: photocatalyst, 0.15 g; CoOₓ loading, 0.5 wt %; 0.2 M aqueous AgNO₃ solution, 150 mL; La₂O₃ buffer, 0.15 g; light source, 300 W xenon lamp (λ≥420 nm).

FIG. 8 is a graph of CoOx loading content vs. Rate of O₂ evolution. FIG. 8 specifically showing the effect of CoOₓ cocatalyst loading on photocatalytic performance using Ta₃N₅ nanoparticles synthesized at 1173 K for 4 h from Ta nanopowder (w/oNaCl/Ta). Conditions: photocatalyst, 0.15 g; 0.2 M aqueous AgNO₃ solution, 150 mL; La₂O₃ buffer, 0.15 g; light source, 300 W xenon lamp (λ≥420 nm).

FIG. 9 is an SEM image of NaCl-mixed Ta metal nanopowder (NaCl/Ta) used in an example of the present invention.

FIG. 10A is a bar graph showing nitridation temperature vs. rate of O₂ evolution for catalysts of the present invention-namely Ta₃N₅ nanoparticles obtained from NaCl-mixed Ta nanopowder (NaCl/Ta) nitrided at 1073 K for different time spans: Photocatalytic O₂ evolution activity of Ta₃N₅ nanoparticles obtained from the nitridation of NaCl-mixed Ta nanopowder (NaCl/Ta) at 1073 K for different time spans. Conditions: photocatalyst, 0.15 g; CoOₓ loading, 0.5 wt %; 0.2 M aqueous AgNO₃ solution, 150 mL; La₂O₃ buffer, 0.15 g; light source, 300 W xenon lamp (λ≥420 nm).

FIG. 10B are XRD patterns from the catalysts tested in FIG. 10A.

FIG. 10C are SEM images of the Ta₃N₅ nanoparticles obtained from NaCl-mixed Ta nanopowder (NaCl/Ta) nitrided at 1073 K for different time spans tested in FIG. 10A.

FIG. 11A-C are standard XRD patterns for TaN_{0.1} (FIG. 11A), TaN (FIG. 11B) and Ta₃N₅ (FIG. 11C).

### DETAILED DESCRIPTION OF THE PRESENT INVENTION

The present invention is directed to tantalum nitride nanoparticles, such as Ta₃N₅ nanoparticles that are modified with a metal oxide(s), such as a CoOₓ cocatalyst. The nanoparticles can be a catalyst alone or be part of a catalyst. The catalyst can be used in various methods, such as methods to water split. The present invention is further directed to methods of making the tantalum nitride nanoparticles and the catalyst. Preferably, the tantalum nitride nanoparticles, such as Ta₃N₅ nanoparticles, that are modified with a metal oxide(s), such as a CoOₓ cocatalyst are used as a water oxidation catalyst.

The tantalum nitride nanoparticles can be further modified to serve also as a water reduction catalyst as explained herein. The tantalum nitride nanoparticles serving as a water oxidation catalyst can be used in combination with tantalum nitride nanoparticles serving as water reduction catalyst. The use of dual catalyst can be on the same tantalum nitride nanoparticles or as a mixture of tantalum nitride nanoparticles (a mixture of tantalum nitride nanoparticles as the water oxidation catalyst and tantalum nitride nanoparticles as the water reduction catalyst in combination as a mixture of the two types of nanoparticles).

A specific example of a tantalum nitride is Ta₃N₅.

Other examples of tantalum nitride include, but are not limited to, Ta₄N₅, Ta₅N₆, Ta₂N, and TaN and generally TaNₓ where x ranges from 0.1 to 3.

The tantalum nitride can be a n-type semiconductor, preferably with a narrow bandgap and/or suitable energetic positions of conduction and valance bands straddling the water redox potentials.

The Ta₃N₅ nanoparticles of the present invention can be single crystalline nanoparticles.

The Ta₃N₅ nanoparticles of the present invention can be single crystalline nanoparticles modified with at least one co-catalyst, for instance, modified with a metal oxide with the general formula MOₓ where M represents a metal and Oₓ represents an oxide that is part of the metal oxide. Exemplary metal oxides include CoOₓ, MnOₓ, FeOₓ, NiOₓ, IrOₓ, and RuOₓ. While the specific embodiment of CoOx is described at times herein at the metal oxide, it is to be understood that the details and discussion relating to CoOx equally applies to the other metal oxides for purposes of the present invention.

The Ta₃N₅ nanoparticles can be monodispersed nanoparticles, such as single crystalline Ta₃N₅ monodispersed nanoparticles, where monodispersed refers to having particles of approximately the same size. A monodispersed distribution can be where the particle size of the population of nanoparticles are within 20%, or within 10%, or within 5%, or within 1% of each other. The particle size can be measured by a laser diffraction particle size distribution analyzer such as a Horiba Scientific Partica LA-960V2, or by a dynamic light scattering particle size distribution analyzer such as a Horiba Scientific nanoPartica SZ-100V2 Series.

The nanoparticles of the present invention described above or herein can be nanoparticles that are monodispersed nanoparticles, and have a crystal phase that is a single crystal phase. The crystalline particles of the present invention can be in the substantial absence or detectable absence of minor segregated phases such as Ta, Ca, or similar minor phases.

As a more specific example and referring to a preferred embodiment, the nanoparticles can be single crystalline Ta₃N₅ nanoparticles modified with a CoOₓ cocatalyst, wherein Oₓ represents an oxide that is part of the cobalt oxide.

The metal oxide cocatalyst, such as the CoOₓ cocatalyst, is impregnated onto the Ta₃N₅ nanoparticles in an amount sufficient to serve as a water oxidation catalyst, such as an amount of at least 0.01 wt % based on the total weight of the single crystalline Ta₃N₅ nanoparticles. The amount can be at least 0.05 wt %, or at least 0.1 wt %, or at least 0.25 wt %, or at least 0.5 wt % or more, such as from 0.01 wt % to 1 wt % or more, or from 0.05 wt % to 1 wt %, based on the total weight of the metal oxide modified-Ta₃N₅ nanoparticle photocatalyst (e.g., CoOₓ-modified Ta₃N₅ nanoparticle photocatalyst).

The CoOₓ cocatalyst can be CoO, Co₂O, Co₂O₃, and/or Co₃O₄, or any combination thereof or mixture thereof.

The single crystalline nanoparticles (e.g., Ta₃N₅ nanoparticles modified with at least one co-catalyst, for instance, modified with at least one metal oxide, such as a CoOₓ cocatalyst) can have an apparent quantum yield of at least 5% at 420 nm, at least 7.5%, at least 9%, at least 10% at 420 nm, such as from 5% to 10% or more at 420 nm.

The present invention further relates to a catalyst, such as a photocatalyst that is or includes the single crystalline nanoparticles (e.g., Ta₃N₅ nanoparticles modified with at least one co-catalyst, for instance, modified with at least one metal oxide, such as a CoOₓ cocatalyst).

The catalyst can be a single crystalline nanoparticle formed by a nitridation process, such as NH₃ nitridation.

The catalyst, such as the photocatalyst, of the present invention can have the property of providing an O₂ production that is over 200 μmol/h, over 400 μmol/h or over 600 μmol/h or over 700 μmol/h, such as from 200 μmol/h to 800 μmol/h.

The catalyst, such as the photocatalyst, of the present invention can have the property of providing an apparent quantum yield (AQY) for photocatalytic O₂ evolution reaction (OER) of over 0.1%, such as from 0.1% to 9.4%, such as an amount that is within 20% or within 10% or within 5% of this 9.4% value.

When the catalyst used also includes a water reduction catalyst (as part of the same catalyst or used in combination with the water oxidation catalyst), as described herein, the catalyst, such as the photocatalyst, of the present invention can have the property of providing a solar-to-hydrogen (STH) energy conversion efficiency of over 0.015%, such as from 0.015% to 0.1% or higher.

When the catalyst used also includes a water reduction catalyst (as part of the same catalyst or used in combination with the water oxidation catalyst), as described herein, the catalyst, such as the photocatalyst, of the present invention can have the property of providing an H₂ production that is over 5 μmol/h, over 7 μmol/h or over 9 μmol/h or over 10 μmol/h or over 12 μmol/h, such as from 5 μmol/h to 13 μmol/h.

When the catalyst used also includes a water reduction catalyst (as part of the same catalyst or used in combination with the water oxidation catalyst), as described herein, the catalyst, such as the photocatalyst, of the present invention can have the property of providing an apparent quantum yield (AQY) for photocatalytic a H₂ evolution reaction (HER) of over 0.15%, such as from 0.15% to 0.54%, such as an amount that is within 20% or within 10% or within 5% of this 0.54% value.

When the catalyst used also includes a water reduction catalyst (as part of the same catalyst or used in combination with the water oxidation catalyst), as described herein, the catalyst can have both the property of providing O₂ production that is over 200 μmol/h, such as from 200 μmol/h to 800 μmol/h. and H₂ production that is over 5 μmol/h, such as from 5 μmol/h to 13 μmol/h and providing the apparent quantum yield for photocatalytic a O₂ evolution reaction (OER) of over 0.1%, such as from 0.1% to 9.4%, and apparent quantum yield (AQY) for photocatalytic a H₂ evolution reaction (HER) of over 0.15%, such as from 0.15% to 0.54%. The catalyst can further have the STH property described herein.

The present invention further relates to a catalyst that includes the single crystalline nanoparticles (e.g., Ta₃N₅ nanoparticles modified with at least one co-catalyst, for instance, modified with a metal oxide, such as a CoOₓ cocatalyst) further modified or including platinum and/or other catalyst metal distributed on a surface of the single crystalline nanoparticles.

The present invention further relates to the use of a catalyst that includes the single crystalline nanoparticles of the present invention along with a metal oxide co-catalyst (e.g., a CoOx co-catalyst(s)) for use as a water oxidation catalyst, and using in combination a water reducing catalyst (as described herein) in photocatalytic water splitting.

The catalyst, such as the photocatalyst, can be a catalyst for at least water oxidation that can comprise, consist essentially of, consists of, include or is one of the crystalline nanoparticles described herein (e.g., Ta₃N₅ nanoparticles modified with at least one co-catalyst, for instance, modified with a metal oxide such as a CoOₓ cocatalyst).

For instance, the Ta₃N₅ nanoparticle photocatalyst can have high photocatalytic performance for O₂ evolution from sacrificial AgNO₃ solution.

The catalyst of the present invention can have higher photocatalytic water oxidation activity than pristine Ta₃N₅ (such as under visible-light irradiation). The higher activity can be 5% or more higher or 10% or more higher or 15% or more higher.

For instance, the nanoparticles or catalyst of the present invention (e.g., Ta₃N₅ nanoparticles modified with at least one co-catalyst, for instance, modified with a metal oxide such as a CoOₓ cocatalyst) can have a rate of O₂ evolution of at least 200 μmol/h, or at least 300 μmol/h, or at least 450 μmol/h, such as a rate of from 200 μmol/h to 800 μmol/h or from 200 μmol/h to 700 μmol/h, or from 200 μmol/h to 600 μmol/h, or from 200 μmol/h to 500 μmol/h.

When more than one tantalum nitride is present in the population of nanoparticles, the distribution between two or more different tantalum nitrides can be even or uneven. For instance, the Ta₃N₅ can be present in the highest weight percent based on the total weight of all tantalum nitrides present. As an option, only one tantalum nitride type is present in the population of nanoparticles.

The single crystalline nanoparticles of the present invention can exhibit single-phase X-ray diffraction (XRD) patterns associated with anosovite-type tantalum nitride, such as anosovite-type Ta₃N₅.

The single crystalline nanoparticles of the present invention can have a variety of shapes. For instance, the nanoparticles can have a shape such that the nanoparticles are considered nanorod shaped particles and/or spherical shaped particles, such as monodispersed nanorod particles or monodispersed spherical particles.

When nanoparticles are nanorod particles, the nanorod particles can have a length. The length can be from 50 nm to 500 nm or higher, such as from 50 nm to 450 nm, from 50 nm to 400 nm, from 50 nm to 350 nm, from 50 nm to 300 nm, from 50 nm to 250 nm, from 50 nm to 200 nm, from 50 nm to 150 nm, from 75 nm to 500 nm, from 100 nm to 500 nm, from 125 nm to 500 nm, from 150 nm to 500 nm, from 175 nm to 500 nm, from 200 nm to 500 nm, from 225 nm to 500 nm, from 250 nm to 500 nm, from 275 nm to 500 nm, from 300 nm to 500 nm and the like, The length can be considered an average length. The length (and width) measurement can be accomplished using images taken from a Scanning Electron Microscope, analyzing a minimum of three images per sample, and measuring a minimum of 10 particles per image; in total, measuring the length and width on the minimum of 30 particles and taking the average length and average width.

When the nanoparticles are nanorods, the nanorods can have an aspect ratio (length/width) of at least 1.2 (e.g., at least 1.3, or at least 1.4, or at least 1.5, or at least 1.7, or at least 2 or at least 2.5, or at least 3, or at least 4 such as from 1.2 to 4 or higher, or from 1.3 to 4, or from 1.4 to 4 and the like).

When the nanoparticles are spherical, the spherical nanoparticles can have an average particle size (e.g., diameter) of from 20 nm to 500 nm or higher, such as from 50 nm to 500 nm or higher, such as from 50 nm to 450 nm, from 50 nm to 400 nm, from 50 nm to 350 nm, from 50 nm to 300 nm, from 50 nm to 250 nm, from 50 nm to 200 nm, from 50 nm to 150 nm, from 75 nm to 500 nm, from 100 nm to 500 nm, from 125 nm to 500 nm, from 150 nm to 500 nm, from 175 nm to 500 nm, from 200 nm to 500 nm, from 225 nm to 500 nm, from 250 nm to 500 nm, from 275 nm to 500 nm, from 300 nm to 500 nm and the like. The measurement/method can be accomplished using a laser diffraction particle size distribution analyzer or by using a dynamic light scattering particle size distribution analyzer.

As an option, the tantalum nitride (e.g., Ta3N5) can have an atomic ratio of surface Ta in the form of Ta₃N₅ (N—Ta—N) that is over 90 at % (e.g., such as 91 at % or higher, or 92 at % or higher, or 95 at % or higher or from 91 at % to 99 at % or from 91 at % to 98 at %, or 92 at % to 98 at %, or 93 at % to 98 at %, or 94 at % to 98 at %).

As an option, the tantalum nitride (e.g., Ta₃N₅) can have an atomic ratio of surface Ta in the form of Ta³⁺ that is below 1 at % (e.g., 0.9 at % or lower, or 0.8 at % or lower, or 0.5 at % or lower, such as 0.001 at % to 0.9 at % or 0.01 at % to 0.5 at %). The atomic ratio of surface Ta in the form of Ta ³⁺ can be undetectable or below 0.001 at %.

As an option, the tantalum nitride (e.g., Ta₃N₅) can have an atomic ratio of surface Ta in the form of TaOₓN_{y} (O—Ta—N) that is 2 at % or more. The atomic ratio can be from 2 at % to 5 at %. x and y here are such that the N/O is preferably greater than 2, or greater than 3, or greater than 4 or greater than 4.5 or greater than 4.8.

The crystalline particles of the present invention can have a charge imbalance resulting in an oxygen-to-anion (O/N+O) molar ratio of 3.0% or higher or 4.0% or higher, such as from 3.0% to about 18% or from 5% to about 18%, or from about 7% to about 18%, or from about 10% to about 18% or from about 12% to about 18% or from 15% or higher.

As an option, the tantalum nitride (e.g., Ta₃N₅) can have a charge imbalance resulting in an oxygen-to-anion (O/N+O) molar ratio of 4.0% or higher (e.g., such as a molar ratio of from 5.0% to about 18%, or from 6.0% to 18%, or from 7.0% to 18%, or from 8.0% to 18%, or from 9.0% to 18%, or from 10% to 18% and the like).

As an option, the tantalum nitride (e.g., Ta₃N₅) can be a tantalum nitride in the substantial or detectable absence of one or more of the following defect species: a reduced species such as Ta³⁺ or Ta⁴⁺, or V_{N}, or O_{N}. A ‘substantial absence’ as used herein and throughout (unless stated otherwise) can be less than less than 15 at % or less than 10 at % or less than 5 at % or less than 2.5 at % or less than 1.5 at % or less than 1 at % or less than 0.5 at % or less than 0.2 at %, or less than 0.1 at %, or less than 0.05 at %, or less than 0.01 at %, or less than 0.001 at %. V_{N} represents a nitrogen vacancy, and can be V_{N}⋅⋅⋅, V_{N}⋅⋅, V_{N}⋅ and V_{NØ}. And, V_{N}⋅⋅⋅, V_{N}⋅⋅, V_{N}⋅ and V_{NØ} represent the V_{N} with zero, one, two and three trapped electrons, respectively, and that only V_{N}⋅⋅ and V_{NØ} with unpaired electrons are possibly EPR-active. O_{N} represents an oxygen impurity (examples include O²⁻).

The tantalum nitride(s) of the present invention can be or serve as a catalyst alone or as an option, can be part of a catalyst. The tantalum nitride of the present invention as a catalyst can be used with one or more co-catalyst, and/or be modified and/or doped with one or more metals and/or impregnated or surface coated with one or more metals.

The catalyst of the present invention can be a photocatalyst. The photocatalyst can be active with various light waves or light regions, such as ultraviolet light and/or visible light (i.e., visible-light region).

The co-catalyst can be at least one metal oxide, such as at least one CoOₓ cocatalyst alone or can be a metal co-catalyst or both. The co-catalyst can be or include or further include platinum (Pt). The co-catalyst can be or include or further include a metal such as, but not limited to, gold, platinum, cobalt, palladium, silver, nickel or any combinations thereof. The co-catalyst can be or include or further include Cr₂O₃.

A co-catalyst such as a metal co-catalyst (e.g., Pt) can be used in combination with another co-catalyst, such as a CoOₓ cocatalyst or Cr₂O₃.

The tantalum nitride(s) of the present invention can serve as a catalyst, such as a photocatalyst, to produce oxygen from the splitting water, and can be used in combination with a second catalyst, such as a photocatalyst, that can produce hydrogen from the splitting water.

Thus, as an option, the present invention can be a combination of two catalysts, a water oxidation catalyst and a water reduction catalyst. The two catalysts can be used together as a mixture. The two catalysts can be used in sequence-where the water oxidation catalyst is utilized followed by the water reduction catalyst or where the water reduction catalyst is utilized followed by the water oxidation catalyst. The two catalysts can be used such that both are added separately for the water splitting reaction but can be present together during the water splitting reaction.

When two catalysts are used, the catalysts can be used in equal amounts (by wt) or one catalyst can be used more than the other catalyst. For instance, the weight ratio of water oxidation catalyst to water reduction catalyst can be a weight ratio of from 10:1 to 1:10 such as from 7.5:1 to 1:7.5 or from 5:1 to 1:5 or from 3:1 to 1:3 or from 2:1 to 1:2 or from 1.5:1 to 1:1.5 or from 1.2:1 to 1:1.2 or from 1.1:1 to 1:1.1 and the like.

As another option, the tantalum nitride(s) of the present invention can serve as a dual catalyst, such as a dual photocatalyst, to produce oxygen from the splitting of water and also produce hydrogen from the splitting of water. In this option, the tantalum nitride is modified in at least two ways so that both catalyst functions can be achieved. The tantalum nitride is modified as described herein (e.g., Ta₃N₅ nanoparticles modified with at least one co-catalyst, for instance, modified with at least one metal oxide, such as a CoOₓ cocatalyst) and also modified or doped with one or two metals such as Zr and/or Mg (e.g., Ta₃N₅:Mg+Zr, or Ta₃N₅:Mg, or Ta₃N₅:Zr or any combination thereof). And, as a further example, all of the Mg²⁺ and/or Zr⁴⁺ cations reside in the crystal lattice of Ta₃N₅. With respect to the further modification aspect, the tantalum nitride can be Ta₃N₅:Mg+Zr alone. The tantalum nitride can be Ta₃N₅:Mg alone. The tantalum nitride can be Ta₃N₅:Zr alone. Each of these can have the Mg and/or Zr residing as cations in the crystal lattice of the Ta₃N₅.

With respect to the dual catalyst and the water reduction function, when the tantalum nitride is or includes Ta₃N₅:Mg+Zr, or Ta₃N₅:Mg, or Ta₃N₅:Zr or any combinations thereof, the tantalum nitride can have Mg-to-cation (e.g., Mg/(Ta+Mg+Zr)) and Zr-to-cation (e.g., Zr/(Ta+Mg+Zr)) ratios that are as high as 9.0 mol. % and 10.2 mol. %, respectively. Mg-to-cation ratio can be from 1 to 9 mol % or from 2 to 9 mol % or from 3 to 9 mol % or from 4 to 9 mol % or from 5 to 9 mol % or from 6 to 9 mol %. The Zr-to-cation ration can be from 1 to 10.2 mol %, from 2 to 10 mol %, from 3 to 10 mol %, from 4 to 10 mol %, from 5 to 10 mol %, from 6 to 10 mol %, from 7 to 10 mol %, or from 8 to 10 mol %.

The tantalum nitride can be modified for the function of water reduction so as to be TaNₓ:M1 or TaNₓ:M1+M2 or any combinations thereof, where x ranges from 0.1 to 3, M1 and M2 represent a metal cation (e.g., Mg, Zr, Li, Sc, Ti, Hf, Al, or Ga) and M1 and M2 are not the same.

The tantalum nitride(s) of the present invention can be or serve as a catalyst alone, such as photocatalyst and has the ability to split water without the assistance of cocatalysts.

The use of one or more cocatalyst or metals is preferred. When both functions, namely water oxidation and water reduction are desired, it is preferred to include a metal such as Pt and optionally Cr₂O₃ or other metal oxide (e.g., forming a Pt/Cr₂O₃ core-shell nanostructure of a uniform thin layer of Cr₂O₃ on the Pt). The loading of a metal such as Pt or other metal can be at least 0.1 wt %, at least 0.5 wt %, or least 0.9 wt %, or at least 1 wt % based on the weight of the catalyst.

The tantalum nitride(s) of the present invention can be or serve as a catalyst alone, such as photocatalyst and has the ability to split water without using sacrificial reagents.

As an option, the tantalum nitride(s) of the present invention can be or serve as a catalyst alone or with one or more co-catalyst(s) as described herein, such as photocatalyst and has the ability to split water and using one or more sacrificial reagents (e.g., sacrificial electron donor), such as, but not limited to, AgNO₃.

The tantalum nitride(s) of the present invention can be or serve as a catalyst alone, such as photocatalyst and has the ability to split water under ultraviolet irradiation or under visible light.

The co-catalyst can be distributed or dispersed on the nanoparticles, such as homogeneously distributed or dispersed on the single crystalline nanoparticles. In the alternative or additionally, the co-catalyst can be mixed with the nanoparticles or used in combination with the nanoparticles in any fashion.

Preferably, the co-catalyst is evenly distributed on the surface of the single crystalline nanoparticles (e.g., a variance of ±10% by weight of co-catalyst anywhere on the surface). As an option, no aggregation of the co-catalyst or the aggregation of co-catalyst with nanoparticles is detectable.

The present invention further relates to a method to make the nanoparticles of the present invention.

The method to make the catalyst (e.g., Ta₃N₅ nanoparticles) can include or involve subjecting either a spherical tantalum powder or salt-valve metal aggregates (such as tantalum aggregates with a salt aggregate, such as NaCl) to a mild nitridation process. The ‘mild nitridation’ can be or include or comprise conducting nitridation that can be under a flow of gas, such as NH₃, at high temperature, such as 700 K or higher or other temperatures (e.g., 700K to 1300K or 725K to 1175K, or 750K to 1175K, or 775K to 1300K, or 800K to 1300K, or 850K to 1300K, or 900K to 1300K, or 925K to 1175K, or 773K to 1223K). The method can be at temperatures of 700K to 1300K or from 900K to 1150K for 10 minutes to 40 hours or more, or from 1 hour to 8 hours, or from 8 hours to 32 hours, or more.

The method to make the tantalum nitride can comprise or include converting tantalum metal (Ta) to a tantalum nitride (e.g., Ta₃N₅). The tantalum can be a spherical tantalum powder (such as having an aspect ratio of 1.4 to 1 or 1.2 to 1 determined by measuring the diameter and the longest diameter measurement over the shortest diameter measurement of a particle) or a flame synthesized tantalum that can optionally be encapsulated with a salt such as NaCl.

The converting to a tantalum nitride can be done by a nitridation step, such as, but not limited to, conducting nitridation of the tantalum that can be under a flow of gas, such as NH₃, at high temperature, such as 700 K or higher or other temperatures (e.g., 700K to 1300K or 725K to 1175K, or 750K to 1175K, or 775K to 1300K, or 800K to 1300K, or 850K to 1300K, or 900K to 1300K, or 925K to 1175K, or 773K to 1223K). The method can be at temperatures of 700K to 1200K or from 900K to 1150K for 10 minutes to 40 hours or more, or from 1 hour to 8 hours, or from 8 hours to 32 hours, or more. Then, the method can then include impregnating the tantalum nitride with at least one cocatalyst such as at least one metal oxide, such as the CoOx cocatalyst or a precursor thereof.

With respect to the nitriding step, the gas for the flow of gas can be a nitrogen containing gas, such as NH₃. The flow rate of the gas can be 10 ml/min or more, 100 ml/min or more, 150 ml/min or more, or 200 ml/min or more where the flow rate is measured at room temperature (25° C.) and room pressure (1 atm). The amount of tantalum converted to tantalum nitride under the nitriding step can be 0.01 g or more, 0.1 g or more, 1.0 g or more, or 10.0 g or more.

The tantalum used can be as follows. The method of making can be where the starting material is a tantalum production process that includes or is a flame synthesis or sodium/halide flame encapsulation (SFE). Techniques employed for the SFE process which can be adapted for preparation of starting tantalum powder for the present invention are described in U.S. Pat. Nos. 5,498,446 and 7,442,227, which are incorporated in their entireties by reference herein. See, also, Barr, J. L. et al., “Processing salt-encapsulated tantalum nanoparticles for high purity, ultra high surface area applications,” J. Nanoparticle Res. (2006), 8:11-22. An example of the chemistry employed for the production of metal powder by the SFE process of the '446 patent is as follows, wherein “M” refers to a metal such as Ta: MClₓ+XNa+Inert→M+XNaCl+Inert. Tantalum pentachloride is an example of a tantalum halide that can be used as the reactant MClₓ, and argon gas may be used as the Inert and carrying gas, in this chemistry. Initially, particles (e.g., Ta) are produced at the flame and grow by coagulation while the salt remains in the vapor phase. The salt condenses onto and/or around the Ta particles with heat loss, and uncoated core particles can be scavenged by the salt particles.

The tantalum used can be a powder such as one obtained by the SFE process without any salt encapsulation or coating.

The tantalum used can be a powder such as one obtained by the SFE process and including a salt layer or encapsulation, such as a NaCl/Ta powder.

The impregnating of the tantalum nitride with at least one cocatalyst such as at least one metal oxide, such as the CoOₓ cocatalyst or a precursor thereof, can be achieved by using a metal-precursor, such as a Co-precursor such as, but not limited to, Co(NO₃)₂·6H₂O. Other examples of metal precursors include, but are not limited to, Mn(NO₃)₂·(H₂O)ₙ, Fe(NO₃)₃·(H₂O)ₙ, Ni(NO₃)₂·(H₂O)ₙ, Ru(NO₃)₃·(H₂O)ₙ, CoCl₂·(H₂O)ₙ, MnCl₂·(H₂O)ₙ, FeCl₃·(H₂O)ₙ, NiCl₂·(H₂O)ₙ, IrCl₃·(H₂O)ₙand RuCl₃·(H₂O)ₙ.

The method to make the catalyst with co-catalyst can include or involve multiple co-catalyst loadings (e.g., CoOx and Pt loading) of the single crystalline nanoparticles. Each unique co-catalyst can serve to catalyze the same or different chemical reactions. For example, the single crystalline nanoparticles can have a first co-catalyst loading useful for catalyzing water oxidation (production of oxygen) and a second co-catalyst loading useful for catalyzing water reduction (production of hydrogen).

The method of modifying the Ta₃N₅ nanoparticles with CoOx cocatalysts can be accomplished by impregnation, which can be followed by a heating treatment under NH₃ flow. Generally, Ta₃N₅ powder, for instance, can be immersed in an aqueous solution containing the required or desired amount of metal precursor, such as Co(NO₃)₂·6H₂O as the Co precursor. This forms a slurry. The slurry can be continuously stirred with sonication (e.g., strong sonication) or other similar dispersion methods, for a time (e.g., 1 to 5 mins or more) to completely disperse the Ta₃N₅ powder in the metal precursor solution, such as a Co(NO₃)₂ solution. Then the modified nanoparticles can be recovered by any technique, such as by drying in a hot water bath. The resulting powdered mixture can be heated, for instance at temperatures of 500K or higher such as at 773 K for 1 h or other times under a flow of NH₃ gas (100 mL min⁻¹ or flow amount below or above) to obtain the metal oxide Ta₃N₅ nanoparticulate photocatalyst, such as a CoOx-modified Ta₃N₅ nanoparticulate photocatalyst.

The above method can be adapted to other Co precursors and/or other metal precursors to modified the tantalum nitride with this type of co-catalyst.

The co-catalyst loading can involve or include the deposition of one or more co-catalyst (e.g., Pt) by an impregnation-reduction (IMP) method. This method involves dispersing the tantalum nitride (previously loaded with or without a first cocatalyst) with a co-catalyst containing compound or co-catalyst precursor (e.g., Pt containing compound or Pt precursor such as H₂PtCl₆) to form a slurry which can be heated with hot water vapor such as steam until dry. The powder can be then heated at 250° C. for 1 h under a H₂/N₂ gaseous flow (H₂: 20 mL/min; N₂: 200 mL/min) so as to obtain the co-catalyst loaded tantalum nitride.

The co-catalyst loading (e.g., the Pt loading) can involve or include the deposition of co-catalyst (e.g., Pt) by an in-situ photodeposition (PD) method. In this method, the co-catalyst precursor (e.g., Pt precursor) can be added to an aqueous solution containing the tantalum nitride (previously loaded with or without a first cocatalyst) nanoparticles. The co-catalyst (e.g., Pt) can be loaded onto the tantalum nitride nanoparticles in-situ under photocatalytic reaction conditions.

The co-catalyst loading (e.g., Pt loading) can be a combination of the IMP and PD methods. For instance, the co-catalyst loading (e.g., Pt loading) can be in a stepwise method. The IMP-PD stepwise method can involve the deposition of the co-catalyst (e.g., Pt) by IMP as the seed (first step) and further seed growth of the co-catalyst (e.g., Pt) by in-situ PD (second step).

In a combination of IMP and PD methods, the co-catalyst loading (e.g., Pt loading) by the photodeposition (PD) method can account for from 70% to 95% of total co-catalyst loading by wt % of co-catalyst (e.g., Pt loading by wt % Pt).

The catalyst of the present invention can be use in methods to split water or other fluids (such as an aqueous fluid, and where fluid refers to a liquid or gas) and thus produce, for instance, hydrogen (e.g., in the form of hydrogen gas or hydrogen protons) and also produce oxygen (e.g., in the form of oxygen gas or oxygen molecules).

The present invention's nanoparticles (with the metal oxide such as CoOx) are especially useful for the part of the water splitting that produces oxygen and can be used in combination with a catalyst that is especially useful for the part of the water splitting that produces hydrogen. The use of each catalyst (one to produce oxygen and one to produce hydrogen) can be used together or in sequence in any order. As indicated, the same catalyst can be a dual purpose catalyst and achieve both functions, water splitting to produce oxygen and also hydrogen.

More specifically, the present invention further involves a method to catalytically split water into the elements of hydrogen and oxygen, wherein an oxidation reaction to produce O₂ includes the use of any one of the catalyst described herein (e.g., Ta₃N₅ nanoparticles modified with at least one co-catalyst, for instance, modified with a metal oxide such as CoOₓ cocatalyst).

The method to catalytically split water into the elements of hydrogen and oxygen, besides the oxidation reaction to produce O₂, can further include a reduction reaction to produce H₂ utilizing any one of the catalyst (i.e., the water reduction catalyst) described in U.S. Provisional Patent Application No. 63/184,816 filed May 6, 2021 or WO 2022/235721, incorporated in their entirety by reference herein. The details and discussion of the water reduction catalyst and methods to make and use the same as described in U.S. Provisional Patent Application No. 63/184,816 filed May 6, 2021 or WO 2022/235721 can be adopted here to modify or include in the catalyst of the present invention (in the same catalyst or used in combination with the water oxidation catalyst).

Thus, with the present invention, as part of the method, a reduction reaction to produce H₂ can be further included. The reduction reaction can, as an option, utilize single crystalline nanoparticles that are tantalum nitride doped with at least one metal. The reduction reaction can utilize single crystalline nanoparticles that are Ta₃N₅:Mg+Zr, or Ta₃N₅:Mg, or Ta₃N₅:Zr or any combination thereof. The reduction reaction can utilize single crystalline nanoparticles that are Ta₃N₅:Mg+Zr, or Ta₃N₅:Mg, or Ta₃N₅:Zr or any combination thereof along with at least one co-catalyst (e.g., Pt).

The aqueous fluid can be water. The aqueous fluid can be a water-based fluid. The aqueous fluid can be an alcohol.

In the methods of the present invention, the catalyst, such as the photocatalyst can be a heterogeneous phase in contact with the fluid or the solution.

The method can comprise or include applying energy to the water or aqueous fluid in the presence of the catalyst(s) to drive the splitting of water molecules into hydrogen and oxygen.

The energy source can be solar energy. The energy source can be light energy. The energy source can be ultra-violet light. The energy source can be visible light. The energy source can be infra-red (IR) energy. The energy source can be visible-light irradiation. The energy source can provide irradiation that is at least 20 mW/cm² or at least 40 mW/cm² or at least 60 mW/cm² or at least 80 mW/cm² or at least 100 mW/cm², or or at least 200 mW/cm², or or at least 300 mW/cm², or at least 400 mW/cm², or at least 500 mW/cm², or at least 600 mW/cm², or at least 700 mW/cm², or at least 800 mW/cm², or at least 900 mW/cm², or at least 1000 mW/cm².

The catalyst(s) can be suspended or otherwise present in the water or aqueous fluid or other fluid.

The catalyst(s) can be attached to a surface and in contact with the water or aqueous fluid or other fluid.

The water or aqueous fluid or other fluid can be moving or stationary relative to the catalyst(s).

The catalyst can be present in any amounts. For instance, when the catalyst is suspended in water or aqueous fluid or other fluid, the amount can be at least 0.15 g/150 ml fluid or at least 0.2 g/150 ml, or at least 0.5 g/150 ml or other amounts below or above any one of these ranges. Similar amounts can be used when the catalyst is fixed to a surface.

While the present invention and various embodiments are described herein, in developing the present invention, it was unexpectedly discovered that certain parameters and material used to form the Ta₃N₅ can significantly affect catalytic properties. Accordingly, the following methods are especially preferred and the resulting Ta₃N₅ catalyst is especially preferred, especially in use as a photocatalyst.

As one preferred embodiment, the Ta material that is used is spherical Ta metal powder, preferably with an average particle size of from 25 nm to 100 nm or from about 50 nm to 100 nm. Best results were obtained when the average spherical particle size was less than 100 nm. The nitridation of the spherical Ta powder unexpectedly provides a better Ta₃N₅ when nitrated at a temperature of at least 1150K or at least 1160 K or at least 1170 K, such as from 1150K to 1230K or from 1170 K to 1230 K. The amount of nitridation time is best when the time is at least 1 hr, or at least 2 hrs, or at least 3 hrs, or at least 4 hrs, with from 4 to 8 hrs showing the best catalytic properties. The amount of co-catalyst, namely CoOx, was better when the amount was 0.2 wt % to 0.8 wt %, such as from 0.3 wt % to 0.7 wt %, or from 0.35 wt % to 0.5 wt % or about 0.5 wt %. Catalytic activity actually reduced when the CoOx loading went above 0.5 wt %. The most preferred being 0.35 wt % to 0.5 wt % or about 0.5 wt %. These parameters provided a catalyst having excellent crystallinity and low defect density, light absorption and photocatalytic O₂ evolution (e.g., providing high photocatalytic activity for O₂ evolution under visible light irradiation).

As a further preferred embodiment, the Ta material that is used is a salt-mixed Ta metal nanopowder, such as NaCl-mixed Ta metal nanopowder (e.g., NaCl cubic crystals and Ta metal nanoparticles). The salt content, such as NaCl, can be an amount of from 10 wt % to 75 wt %, such as from 25 wt % to 60 wt % or from 35 wt % to 60 wt % or from 40 wt % to 60 wt % or from 50 wt % to 60 wt % or about 55 wt % (based on total weight of Ta and salt). The presence of salt during the nitridation process worked unexpectedly well as a molten salt flux during the nitridation process to promote the formation of highly-dispersed Ta₃N₅ nanoparticulate single crystals. The Ta₃N₅ formed had monodispersed rod-like crystals with smooth facets exposed. The particle size of Ta₃N₅ crystals increases with the nitridation temperature. With this nitridation process, the Ta₃N₅ can have clear lattice fringes from surface to the interior without grain boundary, indicating single-crystalline Ta₃N₅ nanoparticles were formed using salt (NaCl)-mixed Ta metal precursor. The preferred nitridation process conditions are actually lower compared to when spherical Ta is used. Here, a preferred nitridation temperature is from about 1000 K to 1100 K such as 1050 K to 1100 K or about 1073 K. The nitridation time that provided the best properties was 8 hrs to 32 hrs with from about 10 hrs to 24 hrs being more preferred and from 12 hrs to 18 hrs or from 14 hr to 17 hrs or about 16 hrs being most preferred. With such preferred conditions, the catalyst made had the best photocatalytic performance for O₂ evolution and apparent quantum yield (AQY) for the Ta₃N₅ nanoparticle during photocatalytic O₂ evolution on the irradiation wavelength. It was unexpectedly discovered that with the assistance of salt such as NaCl as a flux, well-defined Ta₃N₅ nanoparticulate single crystals without grain boundaries and defect states were obtained. Therefore, considerably high photocatalytic activity for O₂ evolution was achieved on this Ta₃N₅ nanoparticles modified with CoOx cocatalyst. The AQY for photocatalytic O₂ evolution was high, such as at least 5%, for instance from 5% to 10% such as 9.4% at 420 nm (±25 nm). These parameters provided a catalyst having excellent crystallinity and low defect density, light absorption and photocatalytic O₂ evolution (e.g., providing high photocatalytic activity for O₂ evolution under visible light irradiation).

Thus, the present invention, in part, relates to using an appropriate starting material for the production of an active nanoscale single-crystal nitride by thermal NH₃ nitridation, which is useful for forming photocatalysts for solar energy conversion.

The present invention will be further clarified by the following examples, which are intended to be purely exemplary of the present invention.

### EXAMPLES

Material Sourcing.

Flame synthesized (SFE) Ta powder in the form of a Ta metal nanopowder without NaCl (w/oNaCl/Ta), also labelled as Ta nanopowder precursor, and NaCl-mixed Ta metal nanopowder (NaCl/Ta); (NaCl: Ta=55:45 wt %) for Ta₃N₅ synthesis, were supplied by Global Advanced Metals USA, Inc. Co(NO₃)₂·6H₂O (99.95%) as precursor of O₂ evolution cocatalyst, AgNO₃ (99.9%) as a sacrificial electron donor and La₂O₃ (99.9%) a buffer agent were purchased from Kanto Chemical Corporation, FUJIFILM Wako Pure Chemical Corporation, and Kojundo Chemical Laboratory Corporation, respectively.

Synthesis of Ta₃N₅ Nanoparticles.

In the examples, Ta₃N₅ nanoparticles were fabricated by nitridation of Ta metal nanopowder (w/oNaCl/Ta) or NaCl-mixed Ta metal nanopowder (NaCl/Ta). 0.4-0.5 g of Ta metal nanopowder (w/oNaCl/Ta) or 0.6-0.7 g of NaCl-mixed Ta metal nanopowder (NaCl/Ta) was transferred into an alumina tube and nitrided at different temperatures for various time spans under a flow of gaseous NH₃ at 100 mL min⁻¹ (measured at room temperature and pressure). The NaCl-mixed Ta metal nanopowder precursor was ground for 5 min in an agate mortar before nitridation. The nitrided samples were washed with ultrapure water at 343 K for 2 h and then completely dried at room temperature overnight.

Modification of the Ta₃N₅ Nanoparticulate with CoOx cocatalyst.

In the examples, modification of the Ta₃N₅ nanoparticulate photocatalyst with CoOx cocatalysts was conducted by impregnation followed by heating treatment under NH₃ flow. Generally, Ta₃N₅ powder was immersed in an aqueous solution containing the required amount of Co(NO₃)₂·6H₂O as a Co precursor. The slurry was continuously stirred with strong sonication for 5 min to completely disperse the Ta₃N₅ powder in the Co(NO₃)₂ solution. After the slurry was dried in a hot water bath, the resulting powdered mixture was heated at 773 K for 1 h under a flow of NH₃ gas (100 mL min−1) to obtain the CoOx-modified Ta₃N₅ nanoparticulate photocatalyst. The CoOx cocatalyst was loaded to 0.5 wt % of the catalyst in all the examples unless stated otherwise.

Material Characterization.

Where stated, the following analytical techniques were used. X-ray diffraction (XRD) patterns were acquired using a Rigaku MiniFlex 300 powder diffractometer with Cu Kα radiation, operating at 30 kV and 30 mA. UV-vis diffuse reflectance spectra (DRS) were recorded with a spectrophotometer (V-670, JASCO) equipped with an integrating sphere, with a Spectralon standard as a reference for baseline correction. Scanning electron microscopy (SEM) images were obtained on Hitachi SU8020 system and JEOL JSM-7600F. High-resolution transmission electron microscopy (HRTEM) was conducted with a JEOL JEM-2800 system and JEM-2100F system.

Photocatalytic O₂ Evolution Reaction.

Photocatalytic O₂ evolution reactions were carried out in a Pyrex top-illuminated reaction vessel connected to a closed gas-circulation system. 0.15 g of CoOx-modified Ta₃N₅ photocatalyst and 0.15 g of La₂O₃ as pH buffer were dispersed in 150 mL of aqueous AgNO₃ solution (0.2 M). The temperature was maintained at 285 K by circulating cooling water. After completely removing air from the reaction slurry by evacuation, the suspension was irradiated with a 300 W Xenon lamp equipped with a cold mirror and a cut-off filter (L42, λ≥420 nm). The reactant solution was maintained at 288 K by a cooling water system during the reaction. The evolved gas products were analyzed using an integrated thermal conductivity detector-gas chromatography system (TCD-GC) consisting of a GC-8A chromatograph (Shimadzu Corp.) equipped with a Molecular Sieve 5 Å column, with argon as the carrier gas. The sensitivity of the TCD was calibrated by analyzing known amounts of gas introduced into the fully evacuated reaction system containing reaction solutions under illumination. Since deposition of Ag particles on photocatalyst often decreases the O₂ evolution rate, the photocatalytic O₂ evolution activity was estimated from the initial gas evolution rate.

Apparent Quantum Yield Measurement.

Under the O₂ evolution reaction conditions, the apparent quantum yield (AQY) for photocatalytic reaction is given by AQY(%)=[4×R]/I×100, where R and I represent the rate of gas evolution and the incident photon flux, respectively. The coefficient of 4 denotes the generation of one molecule of O₂ involves four electrons in photocatalytic O₂ evolution reaction from sacrificial AgNO₃. The light source was a 300 W Xe lamp (MAX-303 Compact Xenon Light Source, Asahi Spectra) with bandpass filters, for example bandpass filters of 380, 400, 420, 440, 500, 560, and 600 nm central wavelengths (full-width at half-maximum=15 nm), respectively. The number of incident photons was measured using a LS-100 grating spectroradiometer (EKO Instruments Co., Ltd.)

### Example 1

Photocatalytic O₂ evolution on Ta₃N₅ nanoparticles from Ta metal nanopowder.

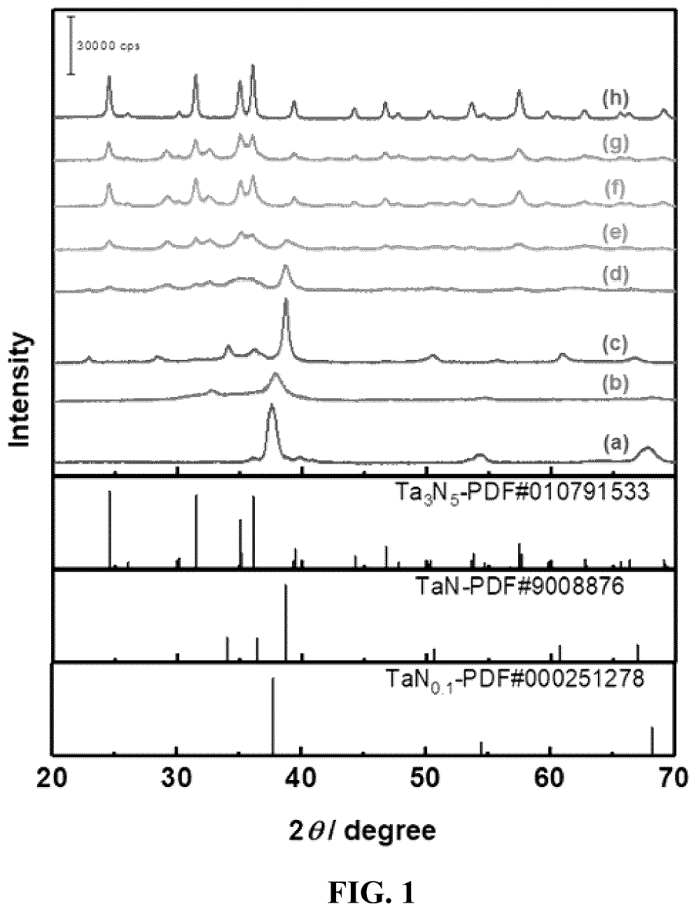

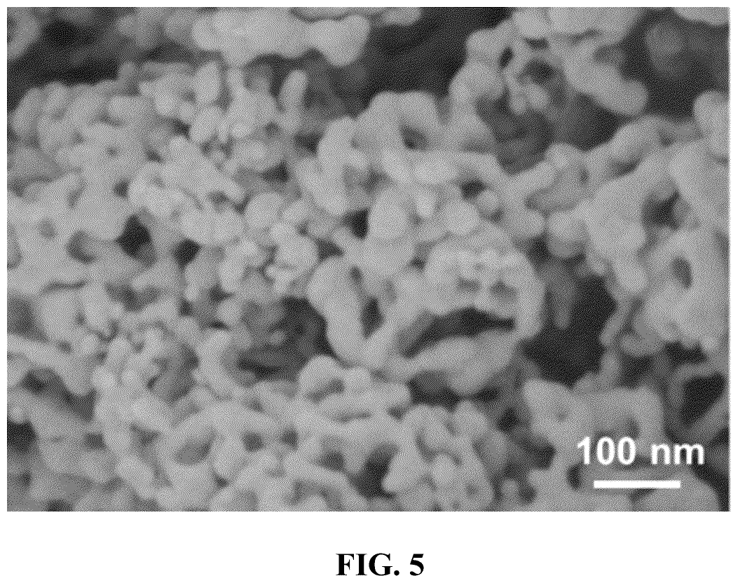

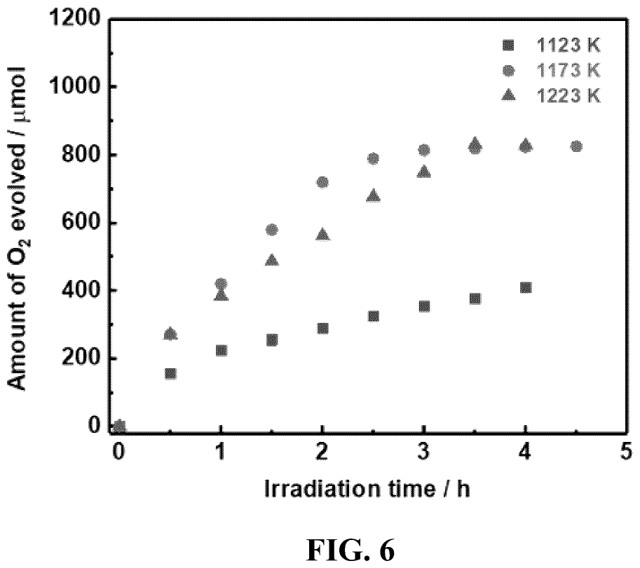

As noted above, Ta₃N₅ is generally synthesized through the nitridation of tantalum oxide (Ta₂O₅) at high temperatures in the presence of NH₃ gas as a nitrogen source. The reaction requires the replacement of three oxygen atoms with two nitrogen atoms to maintain a high oxidation state of Ta⁵⁺. The formation of Ta₃N₅ requires the slow process of solid-state anion diffusion in the reductive NH₃ atmosphere resulting in reduced Ta species and certain amount of oxygen impurity. To avoid this problem, in the examples of the present invention, a spherical Ta metal nanopowder (w/oNaCl/Ta) with an average particle size around 50˜100 nm was utilized as the precursor (FIG. 5). The nitridation of metallic Ta precursor (w/oNaCl/Ta) to form Ta₃N₅ phase is a totally different reaction process, owing to the variation of chemical state of Ta. FIG. 1 presents XRD patterns of Ta nanoparticulate precursor (w/oNaCl/Ta) and intermediate phases of Ta nanopowder nitrided from 773 K to 1173 K. Ta nanoparticulate precursor (w/oNaCl/Ta) was metallic phase (Ta⁰).

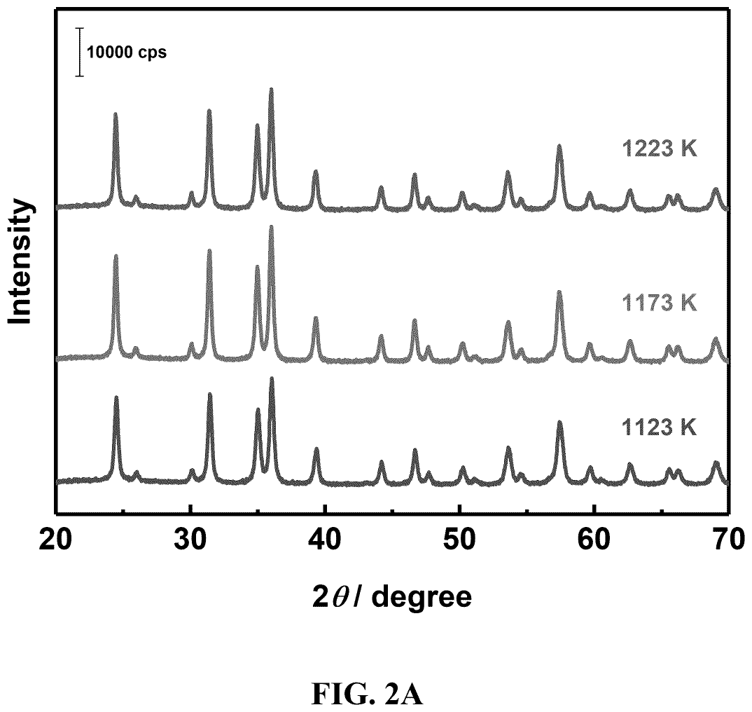

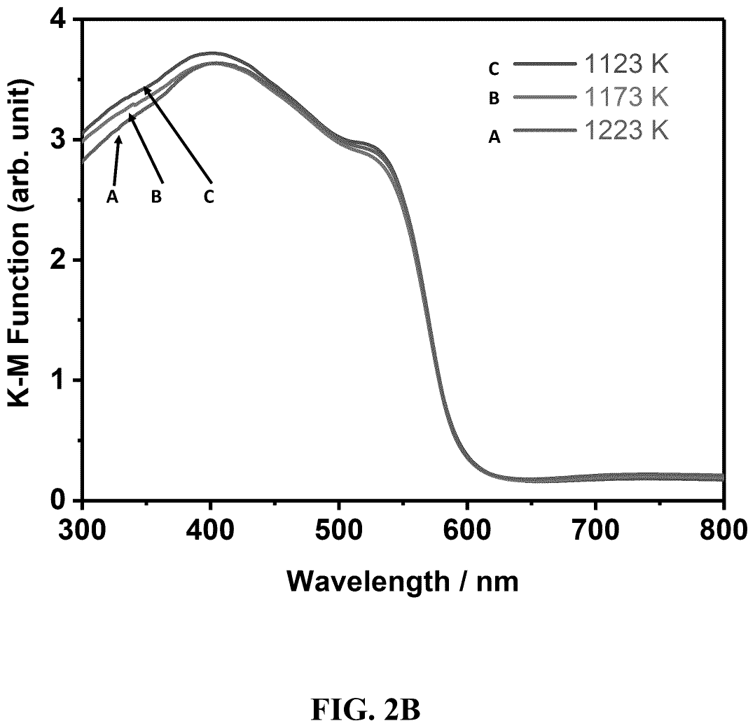

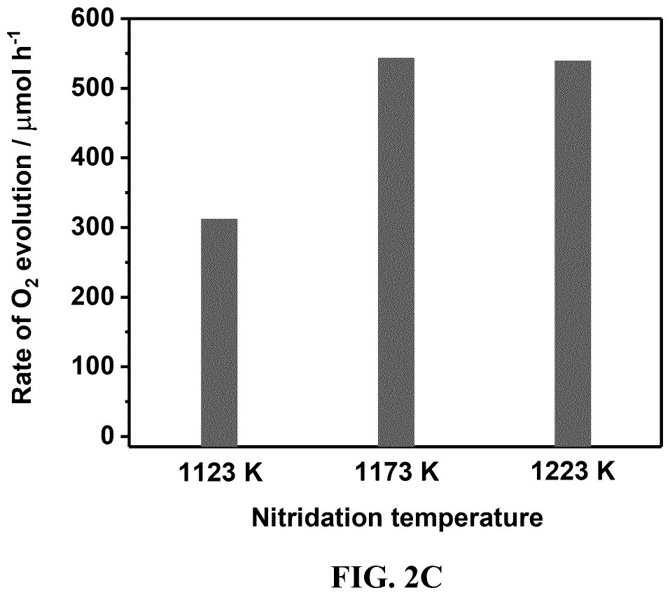

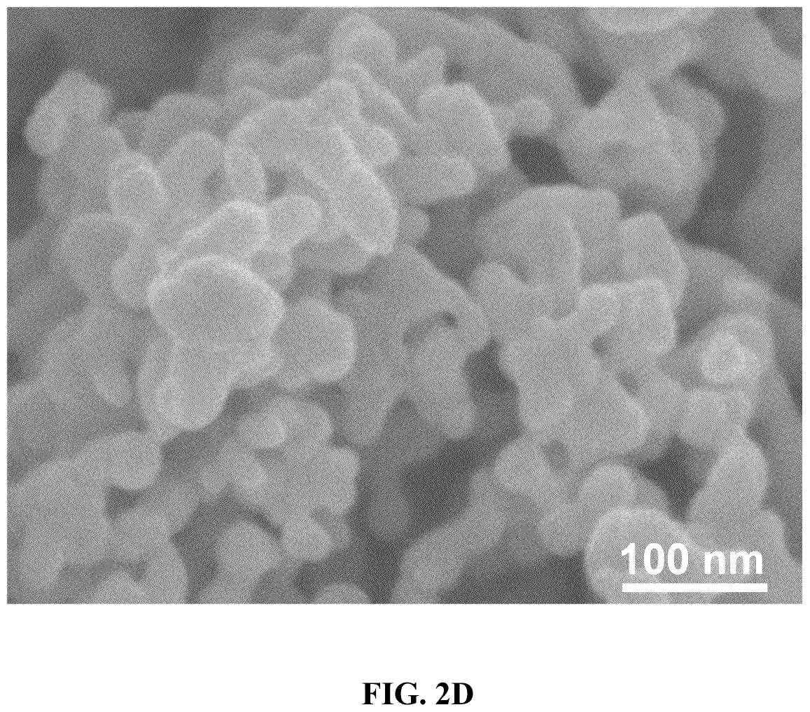

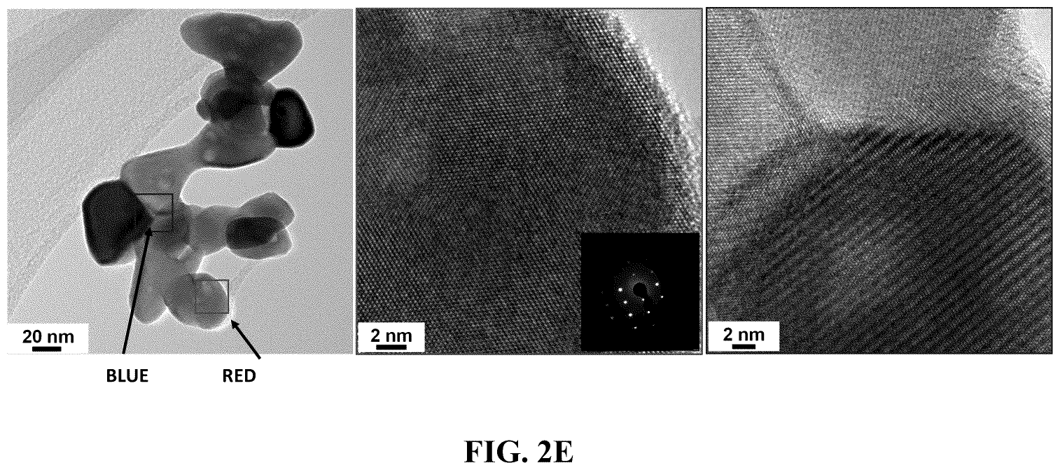

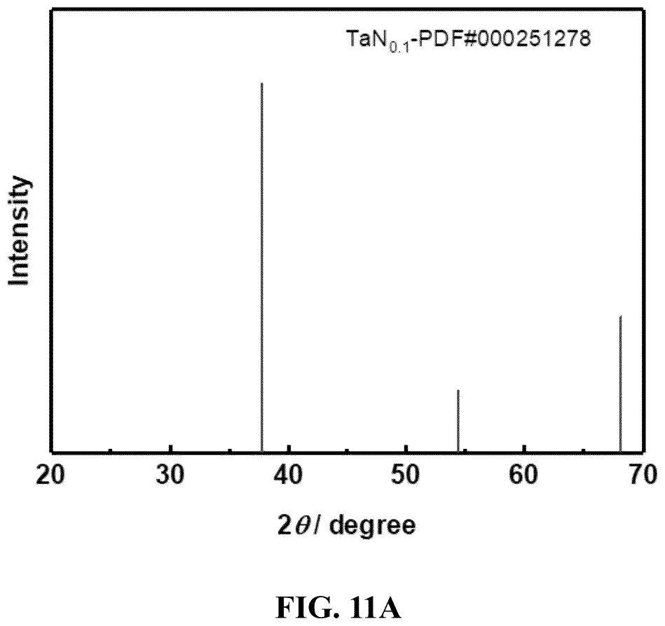

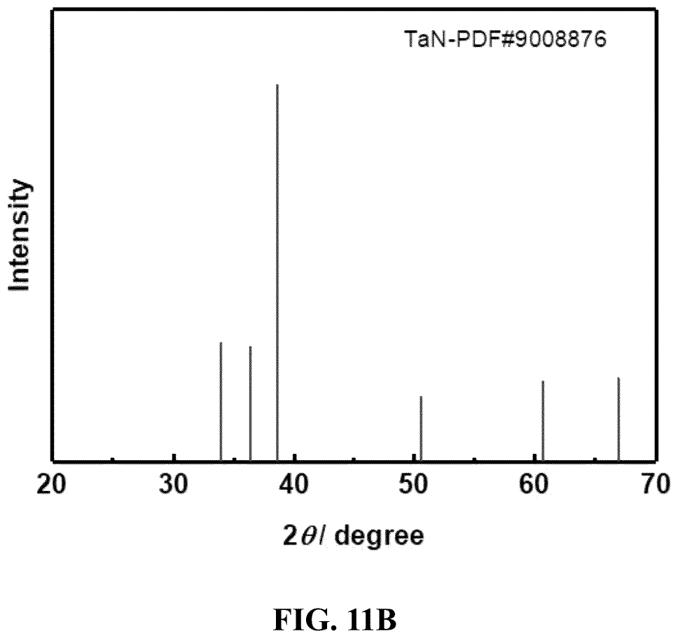

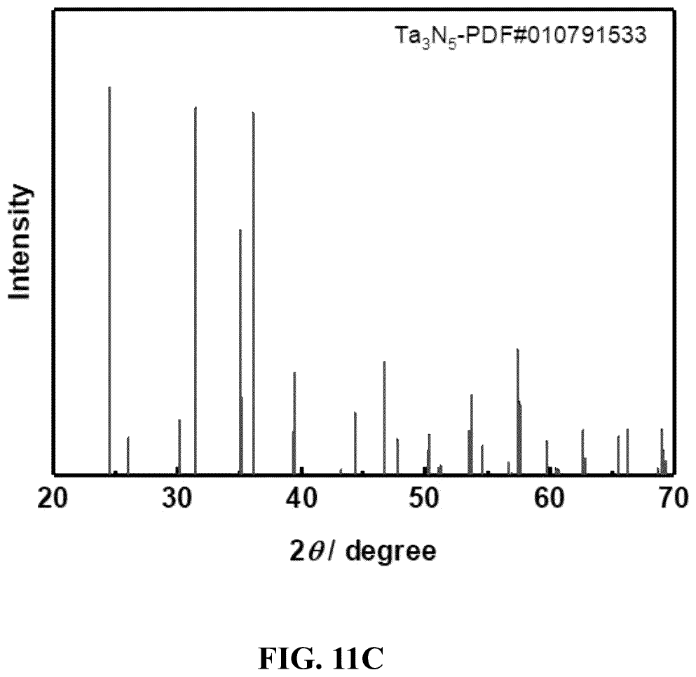

Because nitridation temperature generally plays an important role in determining the crystallinity and defect density of final Ta₃N₅ products, the effects of different nitridation temperature on the crystallinity, light absorption and photocatalytic O₂ evolution of Ta₃N₅ nanoparticles from Ta nanopowder precursor (w/oNaCl/Ta) were examined. As shown in FIG. 2A, XRD patterns of nitrated samples prepared at 1123-1223 K for 4 h are in good agreement with standard Ta₃N₅ pattern (FIG. 11C), indicating that a pure Ta₃N₅ phase was successfully obtained during this temperature range. Upon increasing the nitridation temperature, the intensity of diffraction peak showed a slight change and gradually increases, meaning that the crystallinity of samples treated at higher temperature (1173 K or 1223 K) are better than that at 1123 K. According to the UV-Vis DRS (FIG. 2B), the absorption edges of these samples are located at around 600 nm, consistent with the characteristic photoabsorption of Ta₃N₅. However, the background absorption of the samples increased as the temperature increases, which implied that more defects are formed as the nitridation temperature increased.

Both the crystallinity and defect level will affect the photocatalytic performance of Ta₃N₅, with higher nitriding temperature favoring higher crystallinity (higher photocatalytic performance) and higher defect level (lower photocatalytic performance). The Ta₃N₅ produced at the different nitration temperatures, were modified with the CoOx cocatalyst and the photocatalytic O₂ evolution measured. It was found the Ta₃N₅ nanoparticles treated at 1173 K exhibited the highest photocatalytic activity for O₂ evolution under visible light irradiation (FIG. 2C). Although the Ta₃N₅ treated at 1223 K had as good crystallinity as that at 1173 K, it exhibited more defects than that at 1173 K from the results of background absorption in FIG. 2B, thus showing a slightly lower activity.

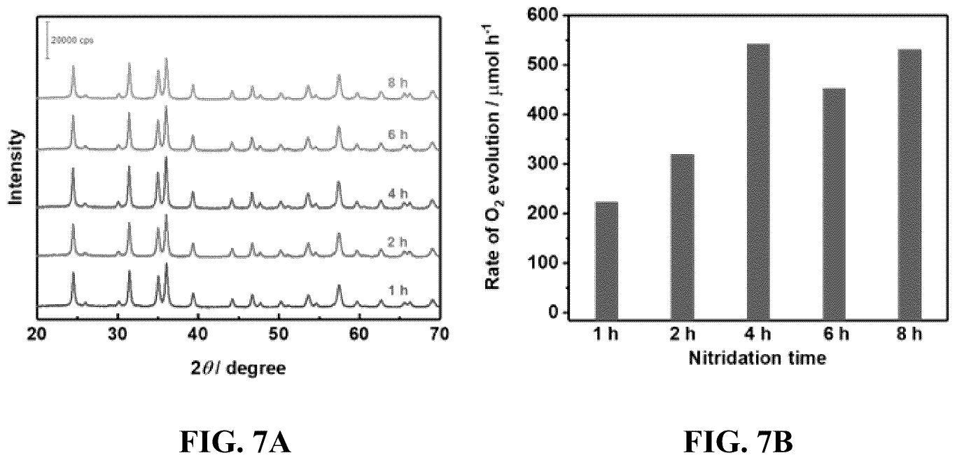

In addition to the nitridation temperature, nitridation period is also important to the photocatalytic activity. Ta nanopowder precursor (w/oNaCl/Ta) was nitrated to form Ta₃N₅ at 1173K from 1 h to 8 h, followed by modification with the CoOx cocatalyst and the photocatalytic O₂ evolution measured. FIG. 7A shows XRD patterns of the Ta₃N₅ and O₂ evolution activity from the Ta₃N₅ modified with the CoOx cocatalyst where the Ta₃N₅ was formed from nitration at 1173K from 1 h to 8 h. The Ta₃N₅ nanoparticles nitrided for 4 h had slightly stronger diffraction intensity and higher photocatalytic performance than other Ta₃N₅ samples. As such, the optimum synthetic condition was determined for the growth of Ta₃N₅ nanoparticulate single crystals using Ta metal nanopowders.

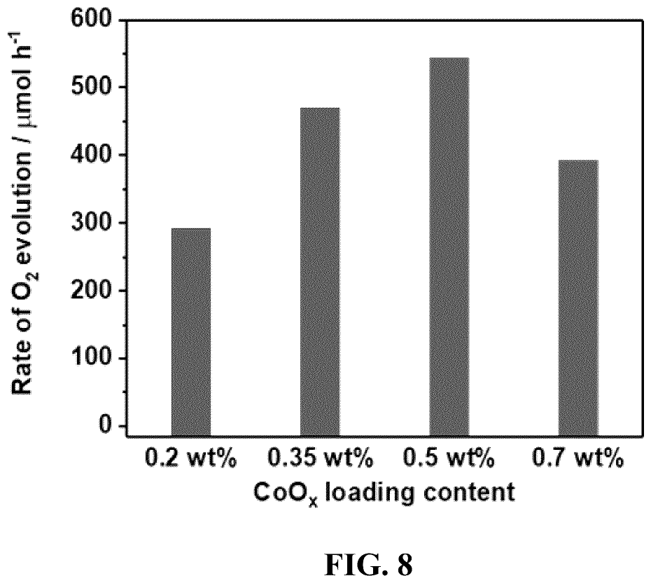

Considering that the O₂-evolving cocatalyst would provide the active catalytic sites on the surface of photocatalyst and improve charge transfer, the effect of the amount of CoOx cocatalyst on photocatalytic performance using Ta₃N₅ nanoparticles synthesized at 1173 K for 4h was investigated (FIG. 8). The Ta₃N₅ nanoparticles synthesized at 1173 K for 4 h from the Ta nanopowder precursor (w/oNaCl/Ta) were modified with the CoOx cocatalyst. By adjusting the amount of Co(NO₃)₂·6H₂O as a Co precursor in the CoOx cocatalyst modification procedure, CoOx cocatalyst loadings of 0.2 wt %, 0.35 wt %, 0.5 wt %, and 0.7 wt % were produced. Photocatalytic O₂ evolution was measured. It was observed that the activity increased with CoOx loading, reaching an optimal level at a CoOx content of 0.5 wt %, and then decreased as the CoOx content increased further.

The detailed morphological information of the Ta₃N₅ nanoparticles nitrided at 1173 K for 4 h was observed by SEM and HRTEM. As shown in FIG. 2D and FIG. 2E, the Ta₃N₅ sample exhibits an irregular crystal shape with a small particle size less than 100 nm. The small crystal size is beneficial to the photocatalytic performance, because the shortened migration distance of electrons and holes to the surface of photocatalyst largely lowers the opportunity for charges recombination. From the enlarged image in the red and blue square area of FIG. 2E (as shown with arrows in FIG. 2E), the clear diffraction fringes in the interior of Ta₃N₅ nanoparticle and the distinct grain boundary between particles are observed, confirming that the Ta₃N₅ nanoparticles were well-crystallized single crystals, with some aggregation.

### Example 2

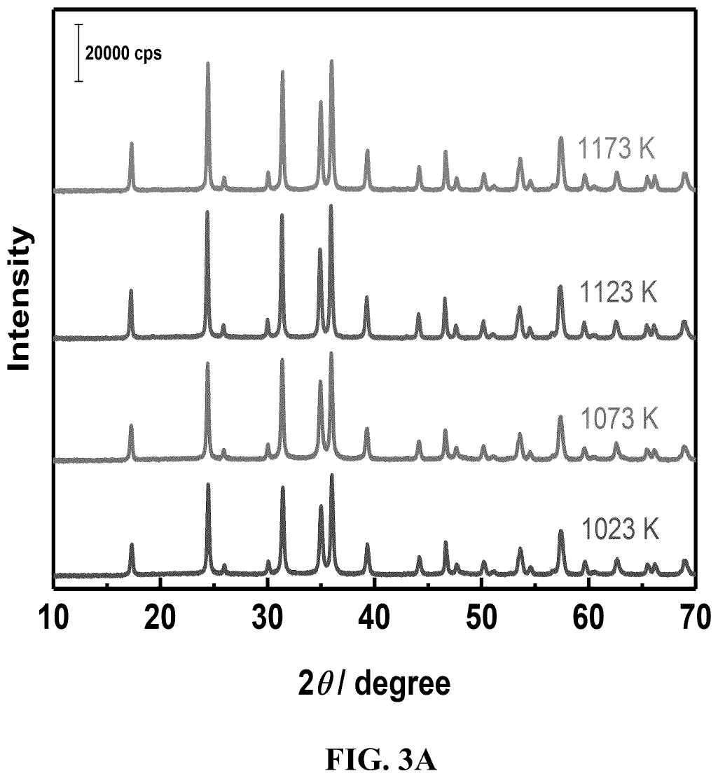

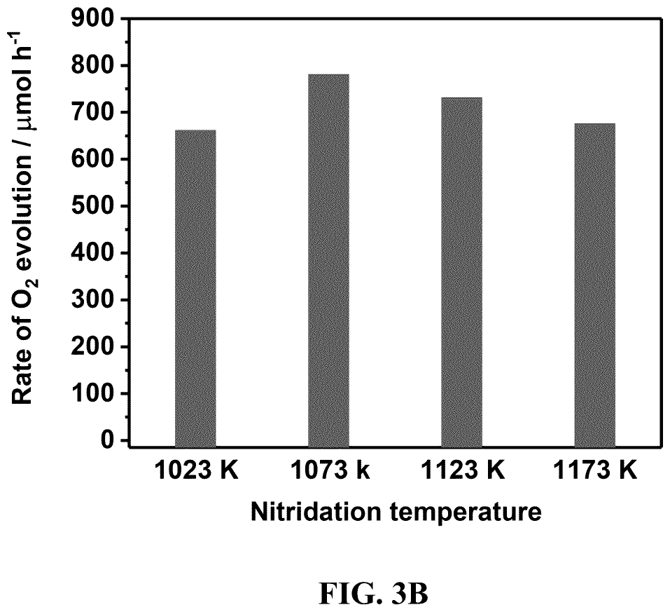

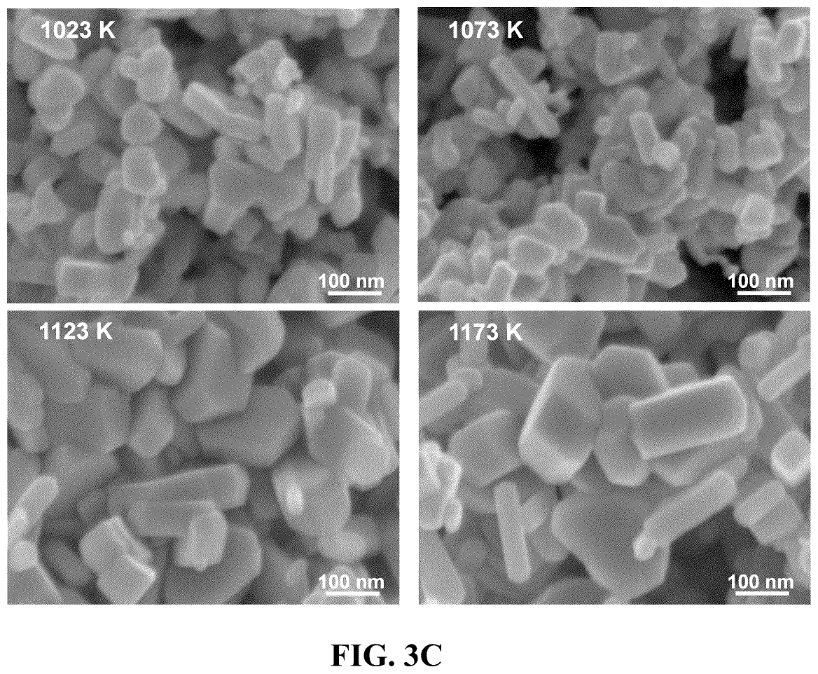

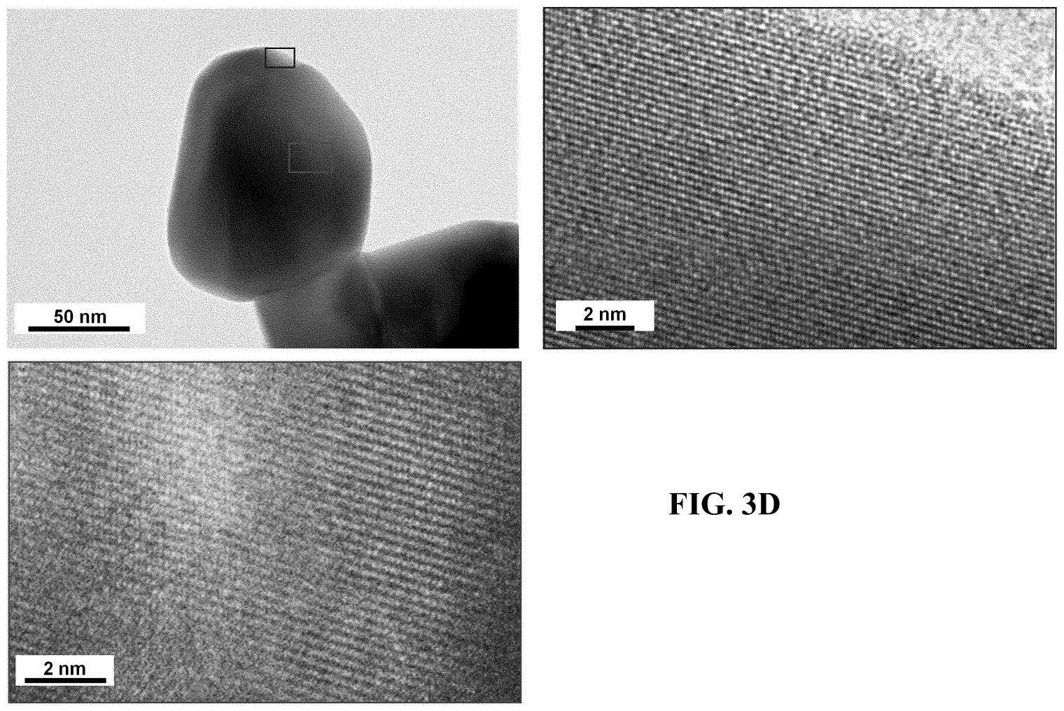

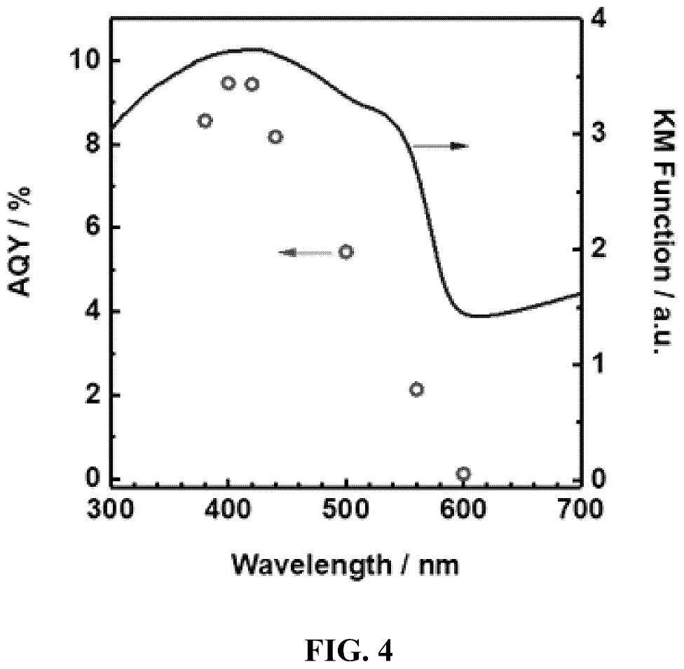

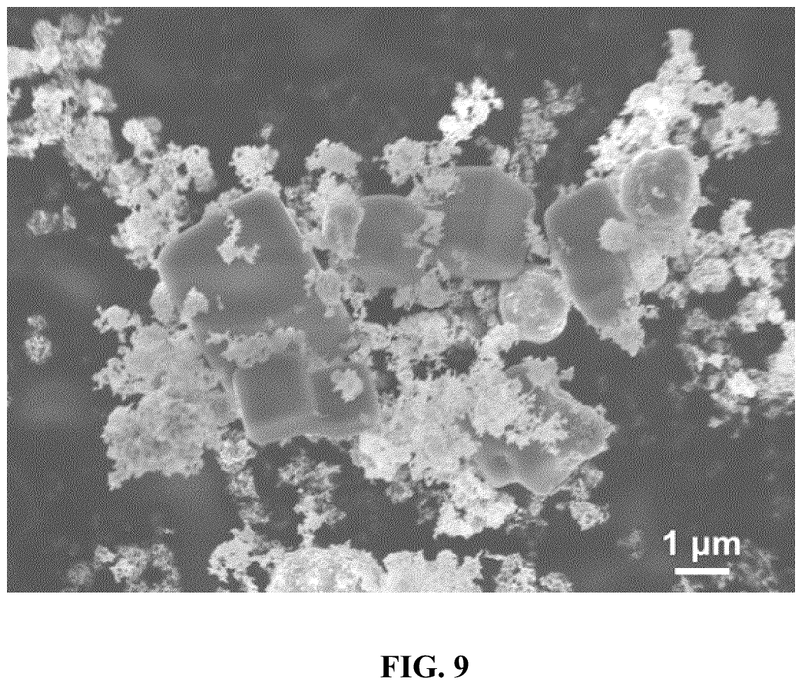

Photocatalytic O₂ evolution on Ta₃N₅ nanoparticles from NaCl-mixed Ta metal nanopowder (NaCl/Ta) originally consisted of NaCl cubic crystals and Ta metal nanoparticles (FIG. 9). When NaCl-mixed Ta metal nanopowder was nitrided under NH₃ flow at 1023 K, 1073 K, 1123 K, and1173 K for 16 h, pure Ta₃N₅ phase was obtained and the crystallinity of Ta₃N₅ became higher as the temperature increased (FIG. 3A). FIG. 3C displays SEM images of Ta₃N₅ nanoparticles from NaCl-mixed Ta metal nanopowders (NaCl/Ta). NaCl with the content of 55 wt % in the mixture worked as a molten salt flux during the nitridation process to promote the formation of highly-dispersed Ta₃N₅ nanoparticulate single crystals. Owing to the function of NaCl flux, the obtained Ta₃N₅ nanoparticles were monodispersed rod-like crystals with smooth facets exposed. The particle size of Ta₃N₅ crystals increased with the nitridation temperature, which is in a good agreement with the increased intensity of XRD patterns (FIG. 3A). HRTEM images of Ta₃N₅ nanoparticles from NaCl-mixed Ta metal nanopowders show clear lattice fringes from surface to the interior without grain boundary, indicating single-crystalline Ta₃N₅ nanoparticles were formed using NaCl-mixed Ta metal precursor (NaCl/Ta) (FIG. 3D).

The Ta₃N₅ nanoparticulate single crystals produced from the NaCl-mixed Ta metal nanopowder (NaCl/Ta) was modified with the CoOx cocatalyst and the photocatalytic O₂ evolution measured. The highly-dispersed Ta₃N₅ nanoparticulate single crystals produced from the NaCl-mixed Ta metal nanopowder (NaCl/Ta) exhibited enhanced photocatalytic performance for O₂ evolution using AgNO₃ as the hole sacrificial reagent (FIG. 3B), as compared with the Ta₃N₅ nanoparticles from Ta metal precursor (w/oNaCl/Ta) (FIG. 2C). The photocatalytic O₂ evolution activity of Ta₃N₅ nanoparticles from NaCl-mixed Ta metal nanopowders (NaCl/Ta) nitrided at 1073 K was the highest among those of other samples at different temperatures (FIG. 3B),

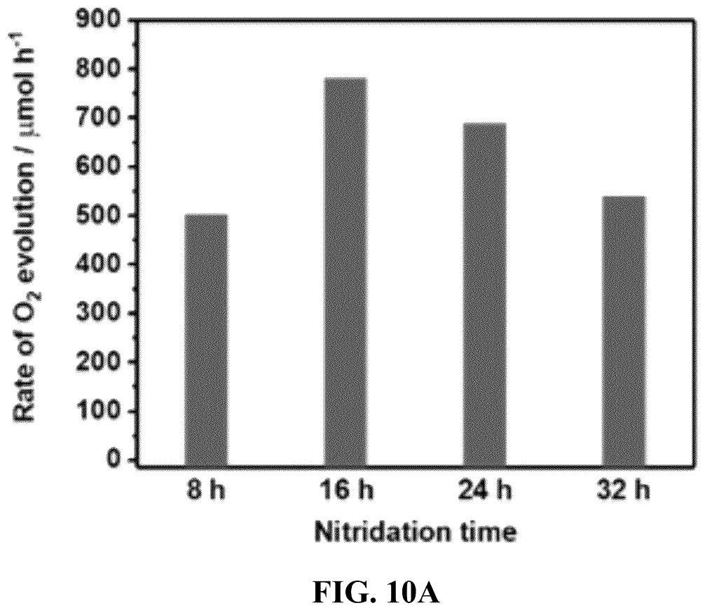

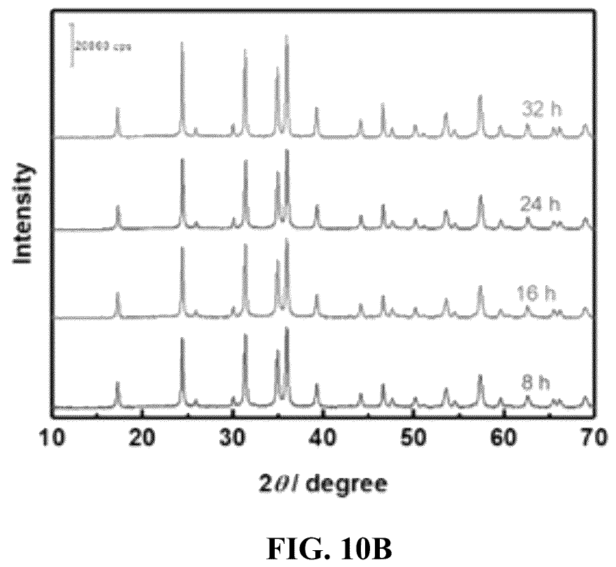

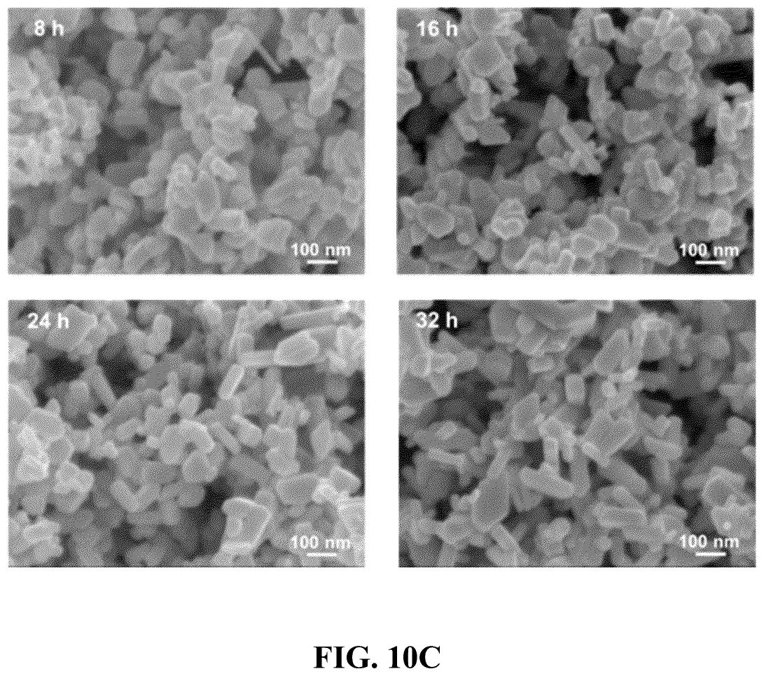

In addition to the nitridation temperature, nitridation period was again investigated as being critical to the photocatalytic activity. NaCl-mixed Ta metal nanopowder (NaCl/Ta) was nitrated to form Ta₃N₅ at 1073K from 8 h to 32 h, followed by modification with the CoOx cocatalyst and the photocatalytic O₂ evolution measured (FIGS. 10A-C). With the elongation of nitridation time from 8 h to 16 h, both the crystallinity and the particle size of Ta₃N₅ nanoparticles increased, resulting in the improvement of photocatalytic O₂ evolution. Further prolonging the nitridation time gradually degraded the O₂ evolution activity of Ta₃N₅ particles, likely due to the extension of charge migration distance in the large particles and their decreased surface area.

The monodispersed single-crystalline Ta₃N₅ nanoparticles synthesized from NaCl-mixed Ta nanopowders (NaCl/Ta) at 1073 K for 16 h exhibited the best photocatalytic performance for O₂ evolution. The dependence of apparent quantum yield (AQY) for the Ta₃N₅ nanoparticle during photocatalytic O₂ evolution on the irradiation wavelength is presented in FIG. 4. The AQY increased at wavelengths shorter than 400 nm, peaked at 400 nm, then declined gradually to the minimum at wavelengths between 420 nm and 600 nm, corresponding well with the absorption profile of Ta₃N₅ nanoparticle prepared from NaCl-mixed Ta nanopowders (NaCl/Ta). The AQY values were 9.4% at 420 nm (±25 nm) and 5.4% at 500 nm (±25 nm), which are comparably high efficiency for Ta₃N₅ photocatalyst simply prepared from precursor without surface or bulk modification. This demonstrates the metallic Ta nanopowder is a promising material to fabricate high-quality Ta₃N₅ nanoparticulate photocatalyst with the absence of defect states and grain boundaries leading to the efficient photocatalytic O₂ evolution.

In summary, as shown in the examples, a single-crystalline Ta₃N₅ nanoparticles was fabricated from a metallic Ta nanopowder or NaCl-mixed Ta nanopowder precursor through an oxidation process in the NH₃ nitridation. The quick transformation of Ta metal to Ta₃N₅ phase enabled the formation of high-quality Ta₃N₅ nanoparticles at relatively mild nitridation condition. Moreover, with the assistance of NaCl as a flux, well-defined Ta₃N₅ nanoparticulate single crystals without grain boundaries and defect states were obtained. Therefore, considerably high photocatalytic activity for O₂ evolution was achieved on this Ta₃N₅ nanoparticles modified with CoOx cocatalyst. The AQY for photocatalytic O₂ evolution was as high as 9.4% at 420 nm (±25 nm). The present findings confirm the validity of using an appropriate starting material for the production of an active nanoscale single-crystal nitrides by thermal NH₃ nitridation, which is useful for forming photocatalysts for solar energy conversion.

The present invention includes the following aspects/embodiments/features in any order and/or in any combination:
1. The present invention including a single crystalline Ta₃N₅ nanoparticles modified with a MOₓ cocatalyst, wherein MOx is a metal oxide, M is a metal and Oₓ represents an oxide that is part of the metal oxide.
2. The single crystalline Ta₃N₅ nanoparticles or method or other embodiment of any preceding or following embodiment/feature/aspect, wherein MOx is a CoOₓ cocatalyst, wherein Oₓ represents an oxide that is part of the cobalt oxide.
3. The single crystalline Ta₃N₅ nanoparticles or method or other embodiment of any preceding or following embodiment/feature/aspect, where the MOx cocatalyst is impregnated onto the Ta₃N₅ nanoparticles in an amount of at least 0.01 wt % based on the total weight of the single crystalline Ta₃N₅ nanoparticles.
4. The single crystalline Ta₃N₅ nanoparticles or method or other embodiment of any preceding or following embodiment/feature/aspect, where the MOx cocatalyst is impregnated onto the Ta₃N₅ nanoparticles in an amount of at least 0.5 wt % based on the total weight of the single crystalline Ta₃N₅ nanoparticles.
5. The single crystalline Ta₃N₅ nanoparticles or method or other embodiment of any preceding or following embodiment/feature/aspect, wherein the MOx cocatalyst is CoO, Co₂O, Co₂O₃, and/or Co₃O₄.
6. The single crystalline Ta₃N₅ nanoparticles or method or other embodiment of any preceding or following embodiment/feature/aspect, wherein the single crystalline nanoparticles have an apparent quantum yield for photocatalytic a O₂ evolution reaction (OER) of over 0.1%.
7. The single crystalline Ta₃N₅ nanoparticles or method or other embodiment of any preceding or following embodiment/feature/aspect, wherein the single crystalline nanoparticles have an apparent quantum yield for photocatalytic a O₂ evolution reaction (OER). of from 0.1% to 9.4%.
8. The single crystalline Ta₃N₅ nanoparticles or method or other embodiment of any preceding or following embodiment/feature/aspect, wherein the single crystalline nanoparticles are also doped with at least one metal.
9. A catalyst (or method of using the same) comprising the single crystalline nanoparticles or single crystalline Ta₃N₅ nanoparticles of any preceding or following embodiment/feature/aspect, with platinum and/or other metal catalyst distributed on a surface of the single crystalline nanoparticles.
10. A photocatalyst (or method of using the same) comprising the single crystalline nanoparticles or single crystalline Ta₃N₅ nanoparticles of any preceding or following embodiment/feature/aspect, and having a solar-to-hydrogen (STH) energy conversion efficiency of over 0.015%.
11. The photocatalyst or single crystalline Ta₃N₅ nanoparticles or method or other embodiment of any preceding or following embodiment/feature/aspect, wherein said solar-to-hydrogen (STH) energy conversion efficiency is from 0.015% to 0.1%.
12. The photocatalyst or single crystalline Ta₃N₅ nanoparticles or method or other embodiment of any preceding or following embodiment/feature/aspect, comprising the single crystalline nanoparticles of any preceding or following embodiment/feature/aspect, and having a H₂ production that is over 5 μmol/h.
13. The photocatalyst or single crystalline Ta₃N₅ nanoparticles or method or other embodiment of any preceding or following embodiment/feature/aspect, wherein said H₂ production is from 5 μmol/h to 13 μmol/h.
14. The photocatalyst or single crystalline Ta₃N₅ nanoparticles or method or other embodiment of any preceding or following embodiment/feature/aspect, and having an apparent quantum yield (AQY) of over 0.15%.
15. The photocatalyst or single crystalline Ta₃N₅ nanoparticles or method or other embodiment of any preceding or following embodiment/feature/aspect, wherein said AQY is from 0.15% to 0.54%.
16. The photocatalyst or single crystalline Ta₃N₅ nanoparticles or method or other embodiment of any preceding or following embodiment/feature/aspect, further having a H₂ production that is over 5 μmol/h or having an apparent quantum yield (AQY) of over 0.15%, or both.
17. A photocatalyst (or method of using the same) comprising single crystalline Ta₃N₅ nanoparticles or other embodiment of any preceding or following embodiment/feature/aspect.
18. A method for water splitting comprising utilizing the photocatalyst or single crystalline Ta₃N₅ nanoparticles any preceding or following embodiment/feature/aspect, in a fluid or solution along with an energy source.
19. A method to catalytically split water into the elements of hydrogen and oxygen, wherein an oxidation reaction to produce O₂ includes utilizing the photocatalyst or single crystalline Ta₃N₅ nanoparticles any preceding or following embodiment/feature/aspect, in a fluid or solution along with an energy source.
20. The method (or catalyst or nanoparticles) of any preceding or following embodiment/feature/aspect, further comprising a reduction reaction to produce H₂.
21. The method (or catalyst or nanoparticles) of any preceding or following embodiment/feature/aspect, wherein the reduction reaction utilizes single crystalline nanoparticles that are tantalum nitride doped with at least one metal.
22. The method (or catalyst or nanoparticles) of any preceding or following embodiment/feature/aspect, wherein the reduction reaction utilizes single crystalline nanoparticles that are Ta₃N₅:Mg+Zr, or Ta₃N₅:Mg, or Ta₃N₅:Zr or any combination thereof.
23. The method (or catalyst or nanoparticles) of any preceding or following embodiment/feature/aspect, wherein the reduction reaction utilizes single crystalline nanoparticles that are Ta₃N₅:Mg+Zr, or Ta₃N₅:Mg, or Ta₃N₅:Zr or any combination thereof along with at least one co-catalyst.
24. A method of making the single crystalline nanoparticles of any preceding or following embodiment/feature/aspect, said method comprising subjecting either a spherical tantalum powder or tantalum aggregates with a salt aggregate or a flame synthesized tantalum that can optionally be encapsulated with a salt to a nitridation process, and said nitridation process comprising conducting nitridation that under a flow of NH₃, at a temperature of 700 K or higher for 10 minutes to 32 hrs to form a tantalum nitride and then impregnating the tantalum nitride with a MOx cocatalyst.
25. The method (or catalyst or nanoparticles) of any preceding or following embodiment/feature/aspect, wherein the temperature is 700K to 1200K for 1 hour to 8 hours.
26. The method (or catalyst or nanoparticles) of any preceding or following embodiment/feature/aspect, said method further comprising impregnating the tantalum nitride with MgCl₂ or other first metal salt and ZrOCl₂ or other second metal salt.
27. The single crystalline Ta₃N₅ nanoparticles or method or other embodiment of any preceding or following embodiment/feature/aspect, wherein the single crystalline nanoparticles are monodispersed nanorod particles.
28. The single crystalline Ta₃N₅ nanoparticles or method or other embodiment of any preceding or following embodiment/feature/aspect, wherein the monodispersed nanorod particles have an average length of from 50 nm to 500 nm.
29. The method (or catalyst or nanoparticles) of any preceding or following embodiment/feature/aspect, wherein said photocatalyst is a heterogeneous phase in contact with the fluid or the solution.
30. The single crystalline Ta₃N₅ nanoparticles or method or other embodiment of any preceding or following embodiment/feature/aspect, wherein energy source is solar energy.
31. The single crystalline Ta₃N₅ nanoparticles or method or other embodiment of any preceding or following embodiment/feature/aspect, wherein the single crystalline nanoparticles provide a rate of O₂ evolution/μmol h⁻¹ of at least 200.
32. The single crystalline Ta₃N₅ nanoparticles or method or other embodiment of any preceding or following embodiment/feature/aspect, wherein the single crystalline nanoparticles provide a rate of O₂ evolution/μmol h⁻¹ of at least 300.
33. The single crystalline Ta₃N₅ nanoparticles or method or other embodiment of any preceding or following embodiment/feature/aspect, wherein the single crystalline nanoparticles provide a rate of O₂ evolution/μmol h⁻¹ of at least 450.
34. The single crystalline Ta₃N₅ nanoparticles or method or other embodiment of any preceding or following embodiment/feature/aspect, said method comprising subjecting said spherical tantalum powder having an average particle size of from 20 nm to 100 nm to said nitridation process with said temperature being from 1150 K to 1230 K for 4 to 8 hours and said impregnating the tantalum nitride with a MOx cocatalyst with a loading of from 0.3 wt % to 0.7 wt %.
35. The single crystalline Ta₃N₅ nanoparticles or method or other embodiment of any preceding or following embodiment/feature/aspect, said method comprising subjecting said tantalum aggregates with said salt aggregate or said flame synthesized tantalum that is encapsulated with said salt to said nitridation process with said temperature being from 1000 K to 1100 K for 8 hrs to 32 hrs and said impregnating the tantalum nitride with a MOx cocatalyst with a loading of from 0.3 wt % to 0.7 wt %.
36. The single crystalline Ta₃N₅ nanoparticles or method or other embodiment of any preceding or following embodiment/feature/aspect, wherein said tantalum aggregates with said salt aggregate or said flame synthesized tantalum that is encapsulated with said salt has a salt content of from 25 wt % to 70 wt % based on weight of tantalum and salt.
37. The method (or catalyst or nanoparticles) of any preceding or following embodiment/feature/aspect, wherein said impregnating comprises mixing said Ta₃N₅ nanoparticles with a metal precursor, such as a Co precursor, to form a dispersed slurry and then recovering and drying the recovered modified nanoparticles and then heating said nanoparticles at temperatures of 500K or higher under a flow of NH₃ gas to obtain the Ta₃N₅ nanoparticles modified with a MOx cocatalyst.
38. Ta₃N₅ nanoparticles modified with a MOx cocatalyst made from the method (or catalyst or nanoparticles) of any preceding or following embodiment/feature/aspect.
39. The single crystalline Ta₃N₅ nanoparticles or method or other embodiment of any preceding or following embodiment/feature/aspect, wherein the single crystalline nanoparticles are also doped with at least two metals.
40. The single crystalline Ta₃N₅ nanoparticles or method or other embodiment of any preceding or following embodiment/feature/aspect, wherein the single crystalline nanoparticles are also co-doped with two metals.
41. The single crystalline Ta₃N₅ nanoparticles or method or other embodiment of any preceding or following embodiment/feature/aspect, wherein the single crystalline nanoparticles are also doped to form Ta₃N₅:Mg+Zr, or Ta₃N₅:Mg, or Ta₃N₅:Zr or any combination thereof.
42. A catalyst comprising single crystalline Ta₃N₅ nanoparticles a) modified with a MOx cocatalyst, wherein Oₓ represents an oxide that is part of the cobalt oxide and 2) modified or doped Zr and/or Mg.
43. A method to catalytically split water into the elements of hydrogen and oxygen, said method comprising utilizing the catalyst or the single crystalline Ta₃N₅ nanoparticles or method or other embodiment of any preceding or following embodiment/feature/aspect,.

The present invention can include any combination of these various features or embodiments above and/or below as set forth in sentences and/or paragraphs. Any combination of disclosed features herein is considered part of the present invention and no limitation is intended with respect to combinable features.

The disclosure herein refers to certain illustrated examples, it is to be understood that these examples are presented by way of example and not by way of limitation. The intent of the foregoing detailed description, although discussing exemplary examples, is to be construed to cover all modifications, alternatives, and equivalents of the examples as may fall within the spirit and scope of the invention as defined by the additional disclosure.

The entire contents of all cited references in this disclosure, to the extent that they are not inconsistent with the present disclosure, are incorporated herein by reference.

The present invention can include any combination of the various features or embodiments described above and/or in the claims below as set forth in sentences and/or paragraphs. Any combination of disclosed features herein is considered part of the present invention and no limitation is intended with respect to combinable features.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

1. Single crystalline Ta₃N₅ nanoparticles modified with a MOₓ cocatalyst, wherein MOx is a metal oxide, M is a metal and Oₓ represents an oxide that is part of the metal oxide.

2. The single crystalline Ta₃N₅ nanoparticles of claim 1, wherein MOx is a CoOₓ cocatalyst, wherein Oₓ represents an oxide that is part of the cobalt oxide.

3. The single crystalline Ta₃N₅ nanoparticles of claim 1, where the MOx cocatalyst is impregnated onto the Ta₃N₅ nanoparticles in an amount of at least 0.01 wt % based on the total weight of the single crystalline Ta₃N₅ nanoparticles.

4. The single crystalline Ta₃N₅ nanoparticles of claim 1, where the MOx cocatalyst is impregnated onto the Ta₃N₅ nanoparticles in an amount of at least 0.5 wt % based on the total weight of the single crystalline Ta₃N₅ nanoparticles.

5. The single crystalline Ta₃N₅ nanoparticles of claim 1, wherein the MOx cocatalyst is CoO, Co₂O, Co₂O₃, and/or Co₃O₄.

6. The single crystalline Ta₃N₅ nanoparticles of claim 1, wherein the single crystalline nanoparticles have an apparent quantum yield for photocatalytic a O₂ evolution reaction (OER) of over 0.1%.

7. The single crystalline Ta₃N₅ nanoparticles of claim 1, wherein the single crystalline nanoparticles have an apparent quantum yield for photocatalytic a O₂ evolution reaction (OER). of from 0.1% to 9.4%.

8. The single crystalline Ta₃N₅ nanoparticles of claim 1, wherein the single crystalline nanoparticles are also doped with at least one metal.

9. A catalyst comprising the single crystalline Ta₃N₅ nanoparticles of claim 1 with platinum and/or other metal catalyst distributed on a surface of the single crystalline nanoparticles.

10. A photocatalyst comprising the single crystalline Ta₃N₅ nanoparticles of claim 1, and having a solar-to-hydrogen (STH) energy conversion efficiency of over 0.015%.

11. The photocatalyst of claim 10, wherein said solar-to-hydrogen (STH) energy conversion efficiency is from 0.015% to 0.1%.

12. A photocatalyst comprising the single crystalline Ta₃N₅ nanoparticles of claim 1, and having a H₂ production that is over 5 μmol/h.

13. The photocatalyst of claim 12, wherein said H₂ production is from 5 μmol/h to 13 μmol/h.

14. A photocatalyst comprising the single crystalline Ta₃N₅ nanoparticles of claim 1, and having an apparent quantum yield (AQY) of over 0.15%.

15. The photocatalyst of claim 14, wherein said AQY is from 0.15% to 0.54%.

16. The photocatalyst of claim 10, further having a H₂ production that is over 5 μmol/h or having an apparent quantum yield (AQY) of over 0.15%, or both.

17. A photocatalyst comprising the single crystalline Ta₃N₅ nanoparticles of claim 1.

18. A method for water splitting comprising utilizing the photocatalyst of claim 17 in a fluid or solution along with an energy source.

19. A method to catalytically split water into the elements of hydrogen and oxygen, wherein an oxidation reaction to produce O₂ includes utilizing the photocatalyst of claim 17.

20. The method of claim 19 further comprising a reduction reaction to produce H₂.

21. The method of claim 20, wherein the reduction reaction utilizes single crystalline Ta₃N₅ nanoparticles that are tantalum nitride doped with at least one metal.

22. The method of claim 20, wherein the reduction reaction utilizes single crystalline Ta₃N₅ nanoparticles that are Ta₃N₅:Mg+Zr, or Ta₃N₅:Mg, or Ta₃N₅:Zr or any combination thereof.

23. The method of claim 20, wherein the reduction reaction utilizes single crystalline Ta₃N₅ nanoparticles that are Ta₃N₅:Mg+Zr, or Ta₃N₅:Mg, or Ta₃N₅:Zr or any combination thereof along with at least one co-catalyst.

24. A method of making the single crystalline Ta₃N₅ nanoparticles of claim 1, said method comprising subjecting either a spherical tantalum powder or tantalum aggregates with a salt aggregate or a flame synthesized tantalum that can optionally be encapsulated with a salt to a nitridation process, and said nitridation process comprising conducting nitridation that under a flow of NH₃, at a temperature of 700 K or higher for 10 minutes to 32 hrs to form a tantalum nitride and then impregnating the tantalum nitride with a MOx cocatalyst.

25. The method of claim 24, wherein the temperature is 700K to 1200K for 1 hour to 8 hours.

26. The method of claim 24, said method further comprising impregnating the tantalum nitride with MgCl₂ or other first metal salt and ZrOCl₂ or other second metal salt.

27. The single crystalline nanoparticles of claim 1, wherein the single crystalline Ta₃N₅ nanoparticles are monodispersed nanorod particles.

28. The single crystalline Ta₃N₅ nanoparticles of claim 27, wherein the monodispersed nanorod particles have an average length of from 50 nm to 500 nm.

29. The method of claim 18, wherein said photocatalyst is a heterogeneous phase in contact with the fluid or the solution.

30. The method of claim 29, wherein energy source is solar energy.

31. The single crystalline Ta₃N₅ nanoparticles of claim 1, wherein the single crystalline nanoparticles provide a rate of O₂ evolution/μmol h⁻¹ of at least 200.

32. The single crystalline Ta₃N₅ nanoparticles of claim 1, wherein the single crystalline nanoparticles provide a rate of O₂ evolution/μmol h⁻¹ of at least 300.

33. The single crystalline Ta₃N₅ nanoparticles of claim 1, wherein the single crystalline nanoparticles provide a rate of O₂ evolution/μmol h⁻¹ of at least 450.

34. The method of claim 24, said method comprising subjecting said spherical tantalum powder having an average particle size of from 20 nm to 100 nm to said nitridation process with said temperature being from 1150 K to 1230 K for 4 to 8 hours and said impregnating the tantalum nitride with a MOx cocatalyst with a loading of from 0.3 wt % to 0.7 wt %.

35. The method of claim 24, said method comprising subjecting said tantalum aggregates with said salt aggregate or said flame synthesized tantalum that is encapsulated with said salt to said nitridation process with said temperature being from 1000 K to 1100 K for 8 hrs to 32 hrs and said impregnating the tantalum nitride with a MOx cocatalyst with a loading of from 0.3 wt % to 0.7 wt %.

36. The method of claim 35, wherein said tantalum aggregates with said salt aggregate or said flame synthesized tantalum that is encapsulated with said salt has a salt content of from 25 wt % to 70 wt % based on weight of tantalum and salt.

37. The method of claim 34, wherein said impregnating comprises mixing said Ta₃N₅ nanoparticles with a metal precursor to form a dispersed slurry and then recovering and drying the recovered modified nanoparticles and then heating said nanoparticles at temperatures of 500K or higher under a flow of NH₃ gas to obtain the Ta₃N₅ nanoparticles modified with a MOx cocatalyst.

38. Ta₃N₅ nanoparticles modified with a MOx cocatalyst made from said method of claim 24.

39. The single crystalline Ta₃N₅ nanoparticles of claim 1, wherein the single crystalline nanoparticles are also doped with at least two metals.

40. The single crystalline Ta₃N₅ nanoparticles of claim 1, wherein the single crystalline nanoparticles are also co-doped with two metals.

41. The single crystalline Ta₃N₅ nanoparticles of claim 1, wherein the single crystalline nanoparticles are also doped to form Ta₃N₅:Mg+Zr, or Ta₃N₅:Mg, or Ta₃N₅:Zr or any combination thereof.

42. A catalyst comprising single crystalline Ta₃N₅ nanoparticles a) modified with a MOx cocatalyst, wherein Oₓ represents an oxide that is part of the cobalt oxide and 2) modified or doped Zr and/or Mg.

43. A method to catalytically split water into the elements of hydrogen and oxygen, said method comprising utilizing the catalyst of claim 42.
